(19) United States
(12) Patent Application Publication
(10) Pub. No.: US 2026/0324500 A1
(43) Pub. Date: Oct. 15, 2026

(54) CHIP STACKING STRUCTURE AND METHOD OF FABRICATING THE SAME

(71) Applicant: Taiwan Semiconductor Manufacturing Company, Ltd., Hsinchu (TW)

(72) Inventors: Chia-Fang Tsai, Hsinchu County (TW); Cheng-Yu Shih, New Taipei City (TW); Yi-Hsiu Chen, Hsinchu City (TW); Yun-Chieh Pai, Taoyuan City (TW); Chun-Ting Liu, Hsinchu City (TW)

(73) Assignee: Taiwan Semiconductor Manufacturing Company, Ltd., Hsinchu (TW)

(21) Appl. No.: 19/178,899

(22) Filed: Apr. 15, 2025

(51) Int. Cl. H01L 25/065; H01L 21/48; H01L 21/56; H01L 21/683; H01L 23/00; H01L 23/31; H01L 23/538; H01L 25/00; H01L 25/11; H01L 25/16

(52) U.S. Cl. CPC H10W 90/00; H10P 72/74; H10W 70/05; H10W 70/611; H10W 70/614; H10W 70/65; H10W 70/685; H10W 74/016; H10W 74/019; H10W 74/117; H10P 72/7436; H10W 70/60; H10W 80/211; H10W 80/312; H10W 80/327; H10W 90/28; H10W 90/288; H10W 90/291; H10W 90/297; H10W 90/722; H10W 90/754; H10W 90/792

(57) ABSTRACT

A chip stacking structure including a first semiconductor die, a second semiconductor die, an insulating encapsulant and a multi-layered bonding film is provided. The second semiconductor die is disposed on and electrically connected to the first semiconductor die. The insulating encapsulant is disposed on the first semiconductor die and laterally encapsulating the second semiconductor die. The multi-layered bonding film is disposed on a surface of the insulating encapsulant and a surface of the second semiconductor die. The multi-layered bonding film includes a planar surface.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semi-conductive layers of material over a semiconductor substrate, and patterning the various material layers using lithography to form circuit components and elements thereon. Dozens or hundreds of integrated circuits are typically manufactured on a single semiconductor wafer. The individual dies are singulated by singulating the integrated circuits along scribe lines. The individual dies are then packaged separately, in multi-chip modules, or in other types of packaging, for example. In semiconductor fabrication, heat dissipation performance and reliability issues of semiconductor packages are highly concerned.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1L are cross-sectional views schematically illustrating a process flow for fabricating chip stacking structures in accordance with some embodiments of the present disclosure.

FIG. 2A through FIG. 2I are cross-sectional views schematically illustrating a process flow for fabricating a Package-on-Package (PoP) structure in accordance with some embodiments of the present disclosure.

FIG. 3A through FIG. 3G are cross-sectional views schematically illustrating a process flow for fabricating chip stacking structures in accordance with some other embodiments of the present disclosure.

FIG. 4 through FIG. 7 are cross-sectional views schematically illustrating various chip stacking structures in accordance with some alternative embodiments of the present disclosure.

FIG. 8 is a cross-sectional view schematically illustrating the face-to-face bonding of the semiconductor wafer and the semiconductor dies in accordance with some other embodiments of the present disclosure.

FIG. 9 is a cross-sectional view schematically illustrating chip stacking structure in accordance with some other embodiments of the present disclosure.

FIGS. 10A and 10B are cross-sectional views schematically illustrating the step portions between the sidewalls of the second semiconductor die and the sidewalls of the insulating encapsulant in accordance with some other embodiments of the present disclosure.

FIGS. 11 and 12 are cross-sectional views schematically illustrating various Chip-on-Wafer-on-Substrate (CoWoS) packages in accordance with various alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase yields and decrease costs.

Package and the method of forming the same are provided in accordance with various exemplary embodiments. The intermediate stages of forming the package are illustrated. The variations of the embodiments are discussed. Throughout the various views and illustrative embodiments, like reference numbers are used to designate like elements.

In some embodiments of the present disclosure, a multi-layered bonding film or an inter-layered film is formed to cover semiconductor dies and an insulating encapsulant laterally encapsulating the semiconductor dies to provide favorable surface flatness for subsequently performed bonding process. The multi-layered bonding film may solve non-bonding issue between semiconductor dies and a carrier, and accordingly, reliability and bonding yields may be enhanced.

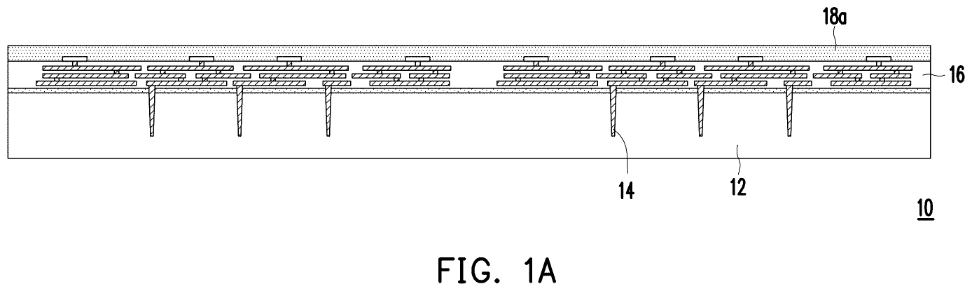

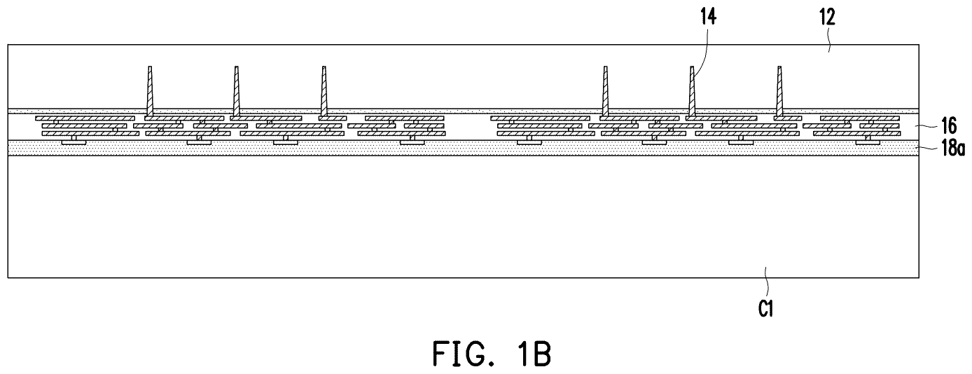

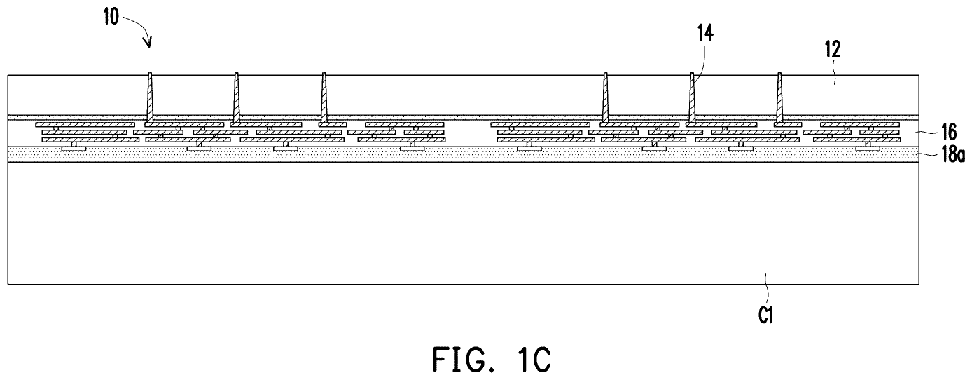

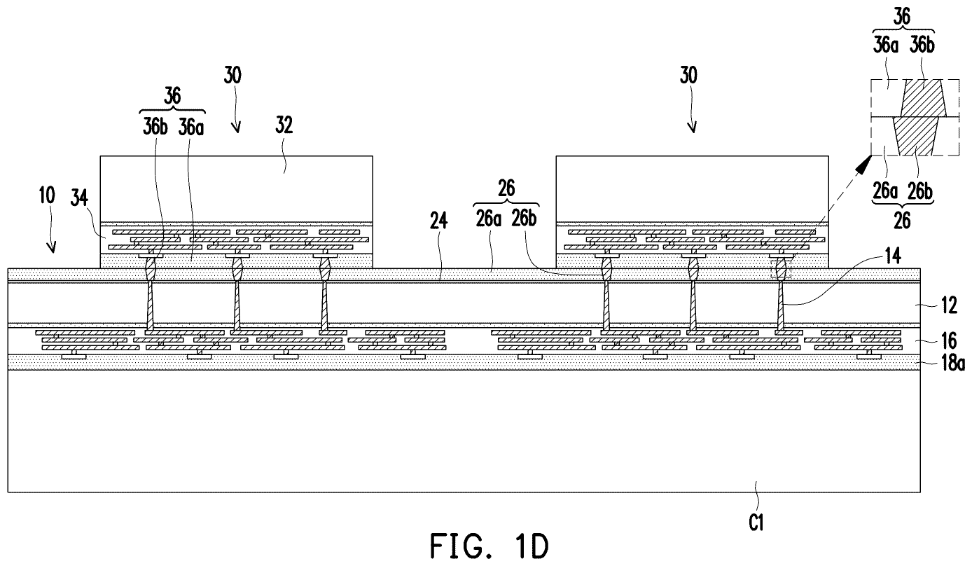

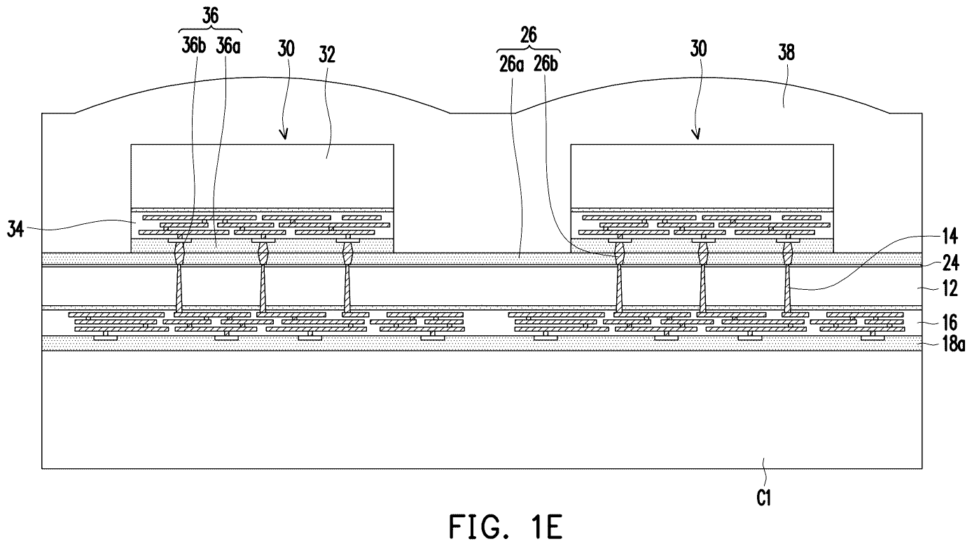

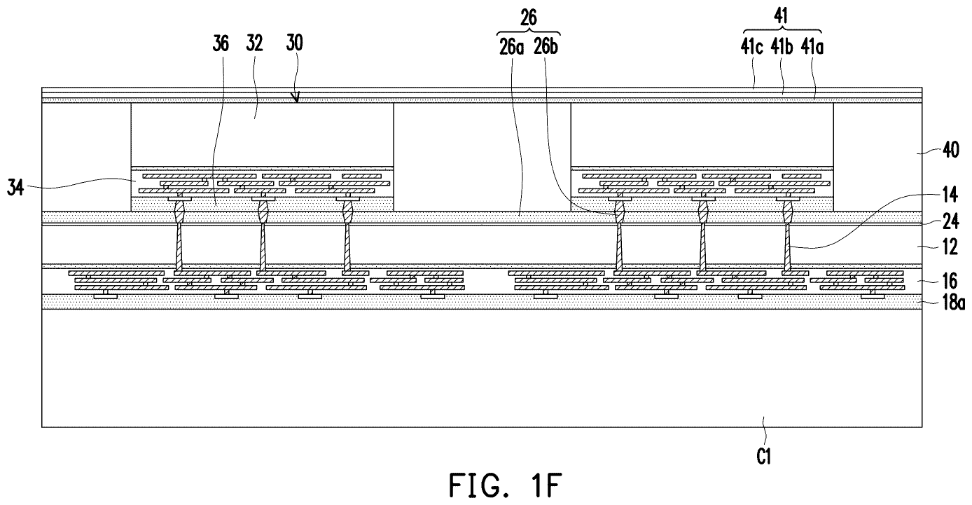

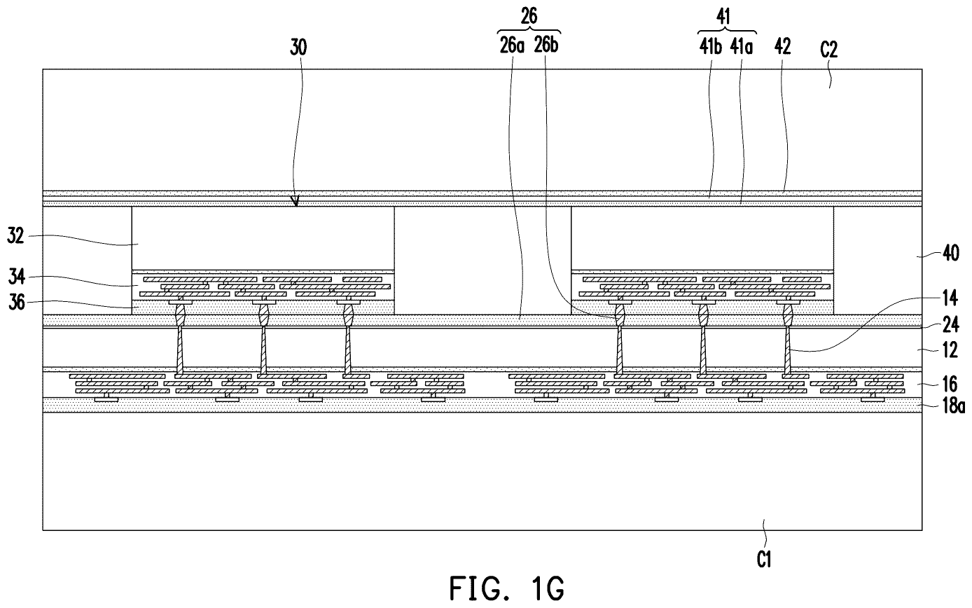

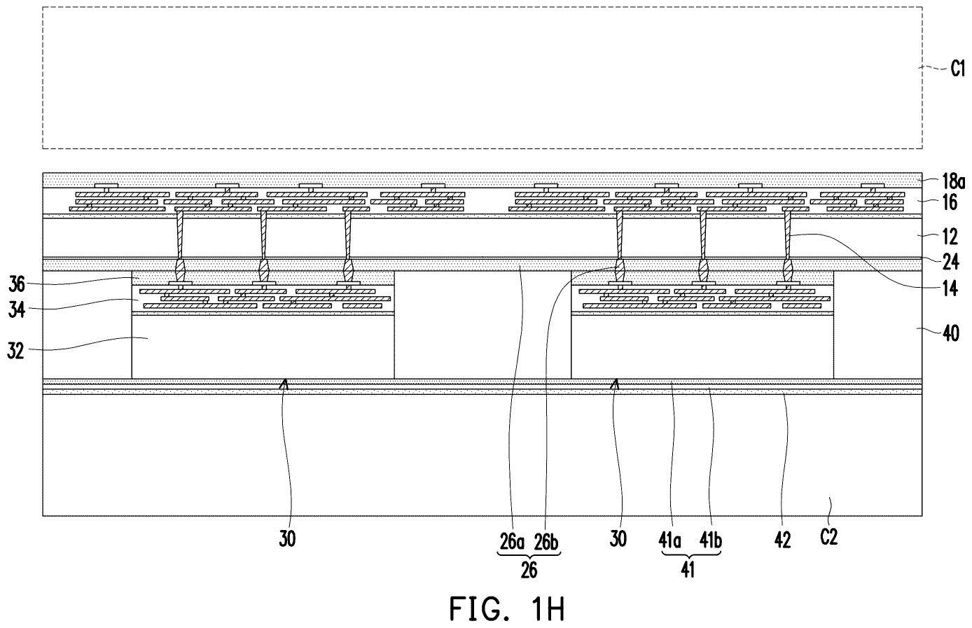

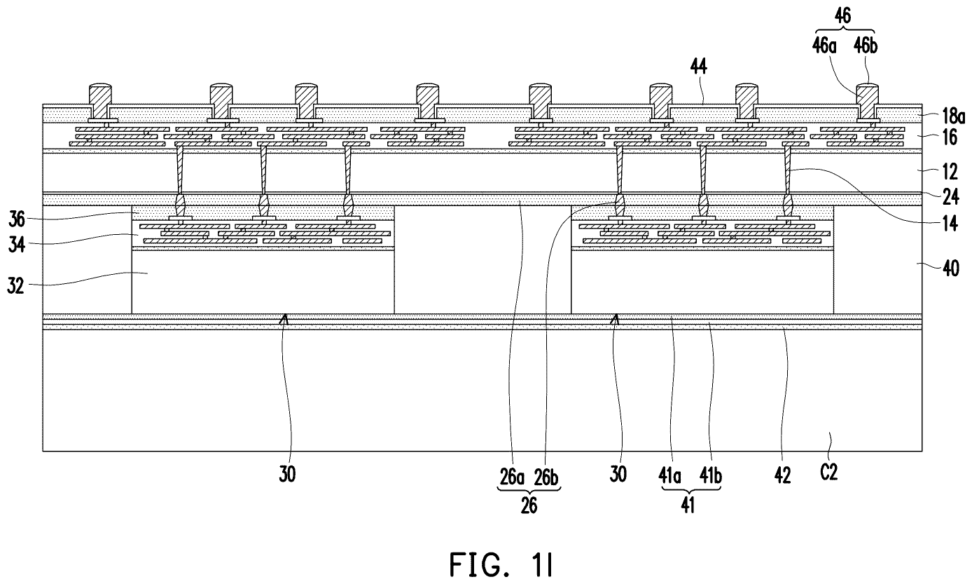

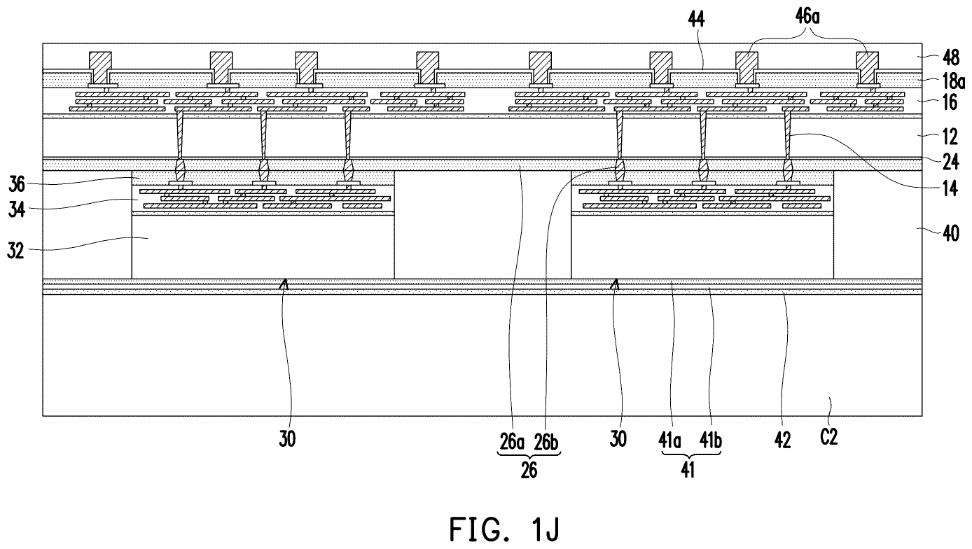

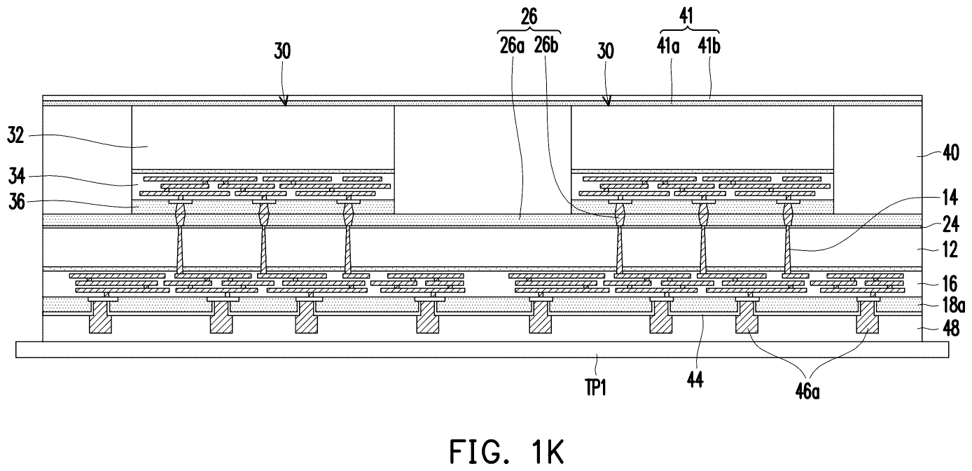

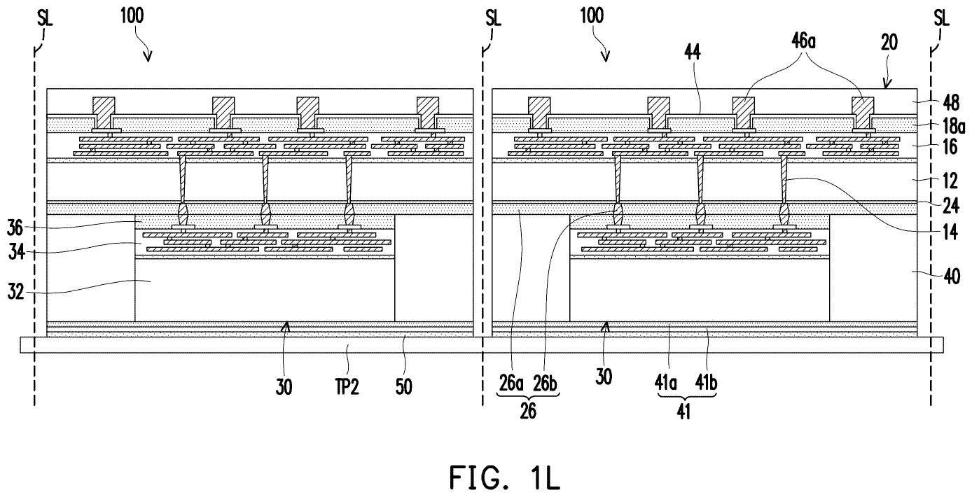

FIG. 1A through FIG. 1L are cross-sectional views schematically illustrating a process flow for fabricating chip stacking structures in accordance with some embodiments of the present disclosure.

Referring to FIG. 1A, a wafer 10 including semiconductor dies is provided. The semiconductor dies in the wafer 10 may be logic dies, System-on-Chip (SoC) dies or other suitable semiconductor dies. The wafer 10 is fabricated through, for example, N3 process, N5 process or other suitable process. The wafer 10 may include a semiconductor substrate 12 (e.g., a semiconductor substrate), through substrate vias 14 embedded in the semiconductor substrate 12, an interconnect structure 16 disposed on the semiconductor substrate 12, and a bonding dielectric layer 18a disposed on the interconnect structure 16, wherein the through substrate vias 14 are electrically connected to the interconnect structure 16. The semiconductor substrate 12 of the wafer 10 may include a crystalline silicon wafer. The semiconductor substrate 12 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the semiconductor substrate 12 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias 14 may be formed by forming recesses in the semiconductor substrate 12 by, for example, etching, milling, laser techniques, a combination thereof, or the like. A thin barrier layer may be conformally deposited over the front side of the semiconductor substrate 12 and in the openings, such as by chemical vapor deposition (CVD), atomic layer deposition (ALD), physical vapor deposition (PVD), thermal oxidation, a combination thereof, or the like. The barrier layer may include a nitride or an oxynitride, such as titanium nitride, titanium oxynitride, tantalum nitride, tantalum oxynitride, tungsten nitride, a combination thereof, or the like. A conductive material is deposited over the thin barrier layer and in the openings. The conductive material may be formed by an electro-chemical plating process, CVD, ALD, PVD, a combination thereof, or the like. Examples of conductive materials are copper, tungsten, aluminum, silver, gold, a combination thereof, or the like. Excess conductive material and barrier layer may be removed from the front side of the semiconductor substrate 12 by, for example, chemical mechanical polishing. Thus, in some embodiments, the through substrate vias 14 may include a conductive material and a thin barrier layer between the conductive material and the semiconductor substrate 12.

The interconnect structure 16 may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the semiconductor substrate 12 and/or the through substrate vias 14. The material of the one or more dielectric layers may include silicon oxide (SiOₓ, where x>0), silicon nitride (SiNₓ, where x>0), silicon oxynitirde (SiOₓN_{y}, where x>0 and y>0) or other suitable dielectric material. The interconnect wirings may include metallic wirings. For example, the interconnect wirings include copper wirings, copper pads, aluminum pads or combinations thereof. In some embodiments, the through substrate vias 14 extend through one or more layers of the interconnect structure 16 and into the semiconductor substrate 12.

The material of the bonding dielectric layer 18a may be silicon oxide (SiOₓ, where x>0), silicon nitride (SiNₓ, where x>0), silicon oxynitirde (SiOₓN_{y}, where x>0 and y>0) or other suitable dielectric material. The bonding dielectric layer 18a may be formed by depositing a dielectric material through a chemical vapor deposition (CVD) process (e.g., a plasma enhanced CVD process or other suitable process).

Referring to FIG. 1A and FIG. 1B, the wafer 10 is picked-up, flipped and placed on and bonded to a carrier C1. The carrier C1 may be a semiconductor wafer such as a silicon wafer having a dielectric layer (e.g., a silicon oxide layer) formed thereon. The carrier C1 may have a round top-view shape and a size of a silicon wafer. For example, both the wafer 10 and the carrier C1 may have an 8-inch diameter, a 12-inch diameter, or the like. The wafer 10 is bonded to the carrier C1 through a wafer-to-wafer bonding process. A bonding process is performed to bond the bonding dielectric layer 18a (e.g., a silicon nitride layer) of the wafer 10 with the carrier C1. The bonding process may be a direct bonding process. After performing the above-mentioned direct bonding process, a dielectric-to-dielectric bonding interface such as silicon oxide-to-silicon nitride (SiOₓ-SiNₓ) bonding interface may be formed between the bonding dielectric layer 18a of the wafer 10 and the carrier C1.

Referring to FIG. 1B and FIG. 1C, a thinning process is performed to partially remove the semiconductor substrate 12 of the wafer 10 until the through semiconductor vias 14 are revealed from the back surface of the semiconductor substrate 12. The thinning process may be a Chemical Mechanical Polish (CMP) process and/or a mechanical grinding process. After performing the above-mentioned thinning process, the through semiconductor vias 14 may protrude from the back surface of the semiconductor substrate 12.

Referring to FIG. 1C and FIG. 1D, a planarization layer 24 is formed over back surfaces of the semiconductor substrate 12 of the wafer 10 such that revealed ends of the through semiconductor vias 14 may substantially level with a top surface of the planarization layer 24. A dielectric material may be formed over the back surfaces of the semiconductor substrates 12 to cover the revealed through semiconductor vias 14. The dielectric material may be or include silicon oxide (SiOₓ, where x>0), silicon nitride (SiNₓ, where x>0), silicon oxynitirde (SiOₓN_{y}, where x>0 and y>0) or other suitable dielectric material. A planarization process such as a CMP process and/or a mechanical grinding process may be performed to partially remove the dielectric material such that the planarization layer 24 is formed on the back surfaces of the semiconductor substrates 12 to laterally encapsulate the ends of the through semiconductor vias 14.

After forming the planarization layer 24, a bonding structure 26 including a bonding dielectric layer 26a and bonding conductors 26b embedded in the bonding dielectric layer 26a is formed over the planarization layer 24 and the through semiconductor vias 14. The material of the bonding dielectric layer 26a may be silicon oxide (SiOₓ, where x>0), silicon nitride (SiNₓ, where x>0), silicon oxynitirde (SiOₓN_{y}, where x>0 and y>0) or other suitable dielectric material, and the bonding conductors 26b may be conductive vias (e.g., copper vias), conductive pads (e.g., copper pads) or combinations thereof. The bonding structure 26 may be formed by depositing a dielectric material through a chemical vapor deposition (CVD) process (e.g., a plasma enhanced CVD process or other suitable process); patterning the dielectric material to form the bonding dielectric layer 26a including openings or through holes; and filling conductive material in the openings or through holes defined in the bonding dielectric layer 26a to form the bonding conductors 26b embedded in the bonding dielectric layer 26a. In some embodiments, the conductive material for forming the bonding conductors 26b may be formed through a chemical vapor deposition (CVD) process (e.g., a plasma enhanced CVD process or other suitable process) followed by a planarization process (e.g., a CMP process and/or a mechanical grinding process).

After forming the bonding structure 26, semiconductor dies 30 are provided on the bonding structure 26. The semiconductor dies 30 may be logic dies, System-on-Chip (SoC) dies or other suitable semiconductor dies. The semiconductor dies 30 are fabricated through, for example, N3 process, N5 process or other suitable process. The semiconductor dies in the wafer 10 and the semiconductor dies 30 provided over the wafer 10 may perform the same function or different functions. For example, the semiconductor dies of the wafer 10 and the semiconductor dies 30 are System on Chip (SoC) dies. Each of the semiconductor dies 30 may respectively include a semiconductor substrate 32 and an interconnect structure 34 disposed on the semiconductor substrate 32. Furthermore, bonding structures 36 may be formed on the interconnect structures 34 of the semiconductor dies 30. The bonding structure 36 includes a bonding dielectric layer 36a and bonding conductors 36b embedded in the bonding dielectric layer 36a. The material of the bonding dielectric layer 36a may be silicon oxide (SiOₓ, where x>0), silicon nitride (SiNₓ, where x>0), silicon oxynitirde (SiOₓN_{y}, where x>0 and y>0) or other suitable dielectric material, and the bonding conductors 36b may be conductive vias (e.g., copper vias), conductive pads (e.g., copper pads) or combinations thereof. The bonding structure 36 may be formed by depositing a dielectric material through a chemical vapor deposition (CVD) process (e.g., a plasma enhanced CVD process or other suitable process); patterning the dielectric material to form the bonding dielectric layer 36a including openings or through holes; and filling conductive material in the openings or through holes defined in the bonding dielectric layer 36a to form the bonding conductors 36b embedded in the bonding dielectric layer 36a. In some embodiments, the conductive material for forming the bonding conductors 36b may be formed through a chemical vapor deposition (CVD) process (e.g., a plasma enhanced CVD process or other suitable process) followed by a planarization process (e.g., a CMP process and/or a mechanical grinding process).

A bonding process (e.g., a chip-to-wafer bonding process) is performed to bond the bonding structures 36 formed on the semiconductor dies 30 with bonding regions of the bonding structure 26. The bonding process may be a bonding process that includes dielectric-to-dielectric bonding and metal-to-metal bonding. After performing the above-mentioned bonding process, a dielectric-to-dielectric bonding interface is formed between the bonding dielectric layer 26a and the bonding dielectric layer 36a, and metal-to-metal bonding interfaces are formed between the bonding conductors 26b and bonding conductors 36b. After performing the bonding process, the semiconductor dies 30 are electrically connected to the semiconductor dies of the wafer 10 through the bonding structures 36 and the bonding structure 26. In some other embodiments, the bonding process may be a bonding process that includes dielectric-to-dielectric bonding, metal-to-metal bonding and dielectric-to-metal bonding. After performing the above-mentioned bonding process, a dielectric-to-dielectric bonding interface is formed between the bonding dielectric layer 26a and the bonding dielectric layer 36a, metal-to-metal bonding interfaces are formed between the bonding conductors 26b and bonding conductors 36b, and dielectric-to-metal bonding interfaces are formed between the bonding conductors 26b and the bonding dielectric layer 36a as well as between the bonding conductors 36b and the bonding dielectric layer 26a. Furthermore, the bonding conductors 26b partially overlap the bonding conductors 36b and partially overlap the bonding dielectric layer 36a; and the bonding conductors 36b partially overlap the bonding conductors 26b and partially overlap the bonding dielectric layer 26a. Furthermore, the bonding conductors 36b and the bonding conductors 26b may have different widths.

As illustrated in FIG. 1D, the semiconductor dies 30 may be disposed above the semiconductor dies of the wafer 10. The lateral dimension (e.g., width and/or length) of the semiconductor dies of the wafer 10 may be greater than the lateral dimension (e.g., width and/or length) of the semiconductor dies 30. In other words, the footprint of the semiconductor dies of the wafer 10 may be greater than that of the semiconductor dies 30. Since the bonding structures 36 are merely bonded with bonding regions of the bonding structure 26, portions of the bonding dielectric layer 26a are not covered by the bonding structures 36. In other words, the portions of the bonding dielectric layer 26a are revealed at this stage.

Referring to FIG. 1E and FIG. 1F, a gap filling material 38 is formed on the bonding structure 26 to cover the back surfaces of the semiconductor dies 30, sidewalls of the semiconductor dies 30, sidewalls of the bonding structures 36, and portions of the bonding dielectric layer 26a which are not covered by the bonding structures 36. The gap filling material 38 may be formed through a deposition process or other suitable process. The material of the gap filling material 38 may be or include a gap filling oxide or other suitable dielectric material. The gap filling material 38 fills the gaps between neighboring semiconductor dies 30 as well as is in contact with the portions of the bonding dielectric layer 26a which are not covered by the bonding structures 36. After forming the gap filling material 38, as illustrated in FIG. 1F, the gap filling material 38 is partially removed until the semiconductor substrates 32 of the semiconductor dies 30 are revealed such that an insulating encapsulant 40 is formed. In some embodiments, the gap filling material 38 may be partially removed through a recessing process for removing portions of the gap filling material 38 followed by a planarization process. The recessing process of the gap filling material 38 may be a patterning process, and the above-mentioned planarization process of the gap filling material 38 may be a CMP process, a mechanical grinding process or combinations thereof. After performing the above-mentioned removal processes of the gap filling material 38, the top surface of the insulating encapsulant 40 may substantially level with the back surfaces of the semiconductor dies 30.

After forming the insulating encapsulant 40, a multi-layered bonding film 41 is formed to cover the insulating encapsulant 40 and the back surfaces of the semiconductor dies 30. The multi-layered bonding film 41 includes a first dielectric layer 41a and a second dielectric layer 41b over the first dielectric layer 41a. The first dielectric layer 41a is thicker than the second dielectric layer 41b. The second dielectric layer 41b includes a planar top surface for subsequently performed bonding process. In some embodiments, the planar top surface of the second dielectric layer 41b can be defined as that the surface topography of the second dielectric layer 41b has a highest point and the lowest point when taking a 1-millimeter wide sample, and the height difference between the highest point and the lowest point is less than 30 angstroms. In some embodiments, the above-mentioned height difference between the highest point and the lowest point ranges from about 0 to about 10 angstroms. In some other embodiments, the above-mentioned height difference between the highest point and the lowest point ranges from about 10 angstroms to about 20 angstroms. In some alternative embodiments, the above-mentioned height difference between the highest point and the lowest point ranges from about 20 angstroms to about 30 angstroms. The first dielectric layer 41a may be a dielectric layer with high thermal conductivity, and the second dielectric layer 41b may be a dielectric layer with relative lower thermal conductivity. In some embodiments, the first dielectric layer 41a of the multi-layered bonding film 41 may be a crystalline film such as an aluminum nitride (AlN) layer, a BN layer, a SiC layer, a BeO layer, a diamond layer, a graphene layer, a Cu layer, a SiGe layer, a TiO₂ layer, a poly-Si layer, an Al₂O₃ layer or a GaN layer, and the second dielectric layer 41b of the multi-layered bonding film 41 may be low-k dielectric layer such as a silicon nitride (SiNₓ, where x>0) layer or a silicon oxide (SiOₓ, where x>0) layer. The thickness of the first dielectric layer 41 a may range from about 500 angstroms to about 3000 angstroms, and the thickness of the second dielectric layer 41b may range from about 200 angstroms to about 500 angstroms. In an embodiment where the first dielectric layer 41a is an AlN layer and the second dielectric layer 41b is a silicon oxide, the thickness ratio of the first dielectric layer 41a and the second dielectric layer 41 b ranges from about 2.5 to about 15. The dielectric constant of the first dielectric layer 41a may range from about 8.6 to about 9.0, and the dielectric constant of the second dielectric layer 41b may range from about 6.5 to about 7.0. The thermal conductivity of the first dielectric layer 41a may range from about 40 Wm⁻¹K⁻¹ to about 321 Wm⁻¹K⁻¹, and the thermal conductivity of the second dielectric layer 41b may range from about 2 Wm⁻¹K⁻¹ to about 30 Wm⁻¹K⁻¹. In an embodiment where the first dielectric layer 41a is an AlN layer and the second dielectric layer 41b is a silicon oxide, the ratio of the thermal conductivity of the first dielectric layer 41a and the thermal conductivity of the second dielectric layer 41b ranges from about 10 to about 160. In an alternative embodiment where the first dielectric layer 41a is an AlN layer and the second dielectric layer 41b is a silicon oxide, the ratio of the thermal conductivity of the first dielectric layer 41a and the thermal conductivity of the second dielectric layer 41b is about 20.

The multi-layered bonding film 41 may further include a sacrificial layer 41c formed to cover the second dielectric layer 41b. The sacrificial layer 41c may be an oxide layer, for example, a tetraethoxysilane (TEOS) formed oxide layer. The sacrificial layer 41c may be then removed to reveal the top surface of the underlying second dielectric layer 41b. In some embodiments, the sacrificial layer 41c is entirely removed to reveal the top surface of the second dielectric layer 41b. The removal of the sacrificial layer 41c may be or include an etch process, a CMP process, a mechanical grinding process, or combinations thereof. The deposition and removal of the sacrificial layer 41c may enhance the surface flatness of the top surface of the second dielectric layer 41b. After the removal of the sacrificial layer 41c, the revealed top surface of the second dielectric layer 41b may have a roughness less than 3 angstroms. In embodiments of the present application, the first dielectric layer 41a of the multi-layered bonding film 41 provides good thermal conductivity, and the second dielectric layer 41b of the multi-layered bonding film 41 provides planar top surface whose roughness is less than 3 angstroms such that the yields of the subsequently performed processes can be increased.

Referring to FIG. 1G, a carrier C2 including a bonding film 42 formed thereon is provided. In some embodiments, the carrier C2 is a glass substrate, a ceramic carrier, or the like. The carrier C2 may have a round top-view shape and a size of a glass substrate. For example, the carrier C2 may have an 8-inch diameter, a 12-inch diameter, or the like. The bonding film 42 may be an oxide layer. In some embodiments, the bonding film 42 may be an oxide layer, for example, a tetraethoxysilane (TEOS) formed oxide bonding layer, which may be subsequently removed along with the carrier C2. In some embodiments, the bonding film 42 is a dielectric film deposited onto the carrier C2. The top surface of the bonding film 42 is substantially planar.

A bonding process is performed to bond the second dielectric layer 41b of the multi-layered bonding film 41 with the bonding film 42 carried by the carrier C2. The bonding process for bonding the second dielectric layer 41b of the multi-layered bonding film 41 with the bonding film 42 carried by the carrier C2 may be a wafer-to-wafer bonding process. After the multi-layered bonding film 41 is bonded with the bonding film 42 carried by the carrier C2, the bonding film 42 and the multi-layered bonding film 41 are between the carrier C2 and the semiconductor dies 30. Furthermore, the gap filling material 38 and the semiconductor dies 30 are spaced apart from the bonding film 42 by the multi-layered bonding film 41.

Referring to FIG. 1G and FIG. 1H, after the resulted structure (shown in FIG. 1F) formed on the carrier C1 is bonded with the bonding film 42 carried by the carrier C2, the carrier C1 is de-bonded from the bonding dielectric layer 18a such that the bonding dielectric layer 18a is revealed.

Referring to FIG. 1H and FIG. 1I, the bonding dielectric layer 18a is patterned to form openings such that the topmost interconnect wirings of the interconnect structures 16 are revealed by the openings formed in the bonding dielectric layer 18a. The formation of the openings in the bonding dielectric layer 18a may be performed through a photolithography process followed by an etch process or other suitable patterning process. A passivation layer 44 including openings formed therein may be formed to cover the bonding dielectric layer 18a such that the topmost interconnect wirings of the interconnect structures 16 revealed by the openings of the passivation layer 44. The formation of the openings in the passivation layer 44 may be performed through a photolithography process followed by an etch process or other suitable patterning process. The width of the openings defined in the passivation layer 44 may be smaller than the width of the openings defined in the bonding dielectric layer 18a. The passivation layer 44 may cover the top surfaces of the bonding dielectric layer 18a. The passivation layer 44 may further extend into the openings defined in the bonding dielectric layer 18a such that the passivation layer 44 is in contact with the topmost interconnect wirings of the interconnect structures 16.

After forming the passivation layer 44, conductive terminals 46 are formed over the passivation layer 44. The conductive terminals 46 are electrically connected to the interconnect wirings of the interconnect structures 16 and protrude from the passivation layer 44. Each of the conductive terminals 46 may respectively include a conductive pillar 46a and a solder cap 46b disposed on the conductive pillar 46a. The conductive pillars 46a fill the openings defined in the passivation layer 44 and protrude from the passivation layer 44. The solder caps 46b covers the top surfaces of the conductive pillars 46a. After forming the conductive terminals 46, a chip probing process may be performed to increase yields. The formation of the conductive terminals 46 may include forming a seed layer (not shown) over the passivation layer 44, forming a patterned mask (not shown) such as a photoresist layer over the seed layer, and then performing a plating process on the exposed seed layer. The patterned mask and the portions of the seed layer covered by the patterned mask are then removed, leaving the conductive terminals 46. A reflow process may be further performed to re-shape the profile of the solder caps 46a. In accordance with some embodiments, the seed layer includes a titanium layer and a copper layer over the titanium layer. The seed layer may be formed using, for example, Physical Vapor Deposition (PVD). The plating may be performed using, for example, electroless plating.

Referring to FIG. 1J and FIG. 1K, after performing the chip probing process, the solder caps 46b are removed and a dielectric layer 48 is formed over the passivation layer 44 to cover the conductive pillars 46a. In other words, the conductive pillars 46a are protected by the dielectric layer 48 and not revealed at this stage. In some embodiments, the dielectric layer 48 is formed of a polymer, which may be a photo-sensitive material such as polybenzoxazole (PBO), polyimide, benzocyclobutene (BCB), or the like. In some other embodiments, the dielectric layer 48 is formed of a nitride such as silicon nitride, an oxide such as silicon oxide, PhosphoSilicate Glass (PSG), BoroSilicate Glass (BSG), Boron-doped PhosphoSilicate Glass (BPSG), or the like.

Referring to FIG. 1J and FIG. 1K, a frame mount process is performed such that the resulted structure carried by the carrier C2 is mounted on a tape TP1 carried by a frame. After performing the frame mount process, the dielectric layer 48 is attached on the tape TP1, and a de-bonding process is then performed such that the carrier C2 is de-bonded from the semiconductor dies 30 and the insulating encapsulant 40. After performing the de-bonding process, the back surfaces of the semiconductor dies 30 and the insulating encapsulant 40 are revealed. During the de-bonding process, the bonding film 42 is also de-bonded from the semiconductor dies 30 and the insulating encapsulant 40. The de-bonding may be performed by irradiating a light such as UV light or laser on the bonding film 42 to decompose the bonding film 42.

Referring to FIG. 1K and FIG. 1L, a tape TP2 carried by another frame is provided, wherein an attachment film 50 is formed on the tape TP2. The resulted structure carried by the tape TP1 is transfer bonded onto the attachment film 50. Then, a singulation process is performed along scribe lines SL such that singulated chip stacking structures 100 (i.e., SoIC structures) are obtained. During the singulation process, the dielectric layer 48, the passivation layer 44, the bonding dielectric layer 18a, the interconnect structure 16, the planarization layer 24, the semiconductor substrate 12, the bonding structure 26, the insulating encapsulant 40 and the attachment film 50 are cut along scribe lines SL. In some embodiments, after performing the singulation process, in each singulated chip stacking structure 100, the insulating encapsulant 40 laterally encapsulates the semiconductor die 30, wherein sidewalls of the insulating encapsulant 40 substantially align with sidewalls of the dielectric layer 48, the passivation layer 44, the bonding dielectric layer 18a, the interconnect structure 16, the planarization layer 24, the semiconductor substrate 12, the bonding structure 26 and the attachment film 50.

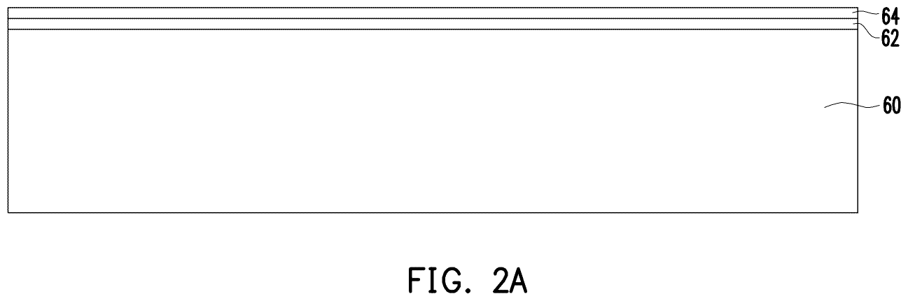

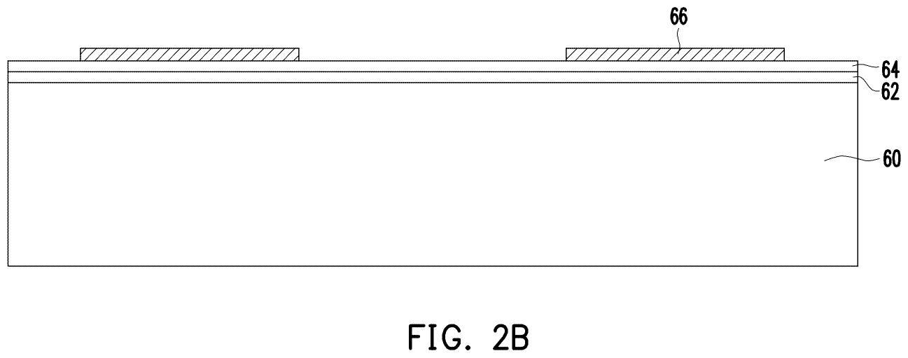

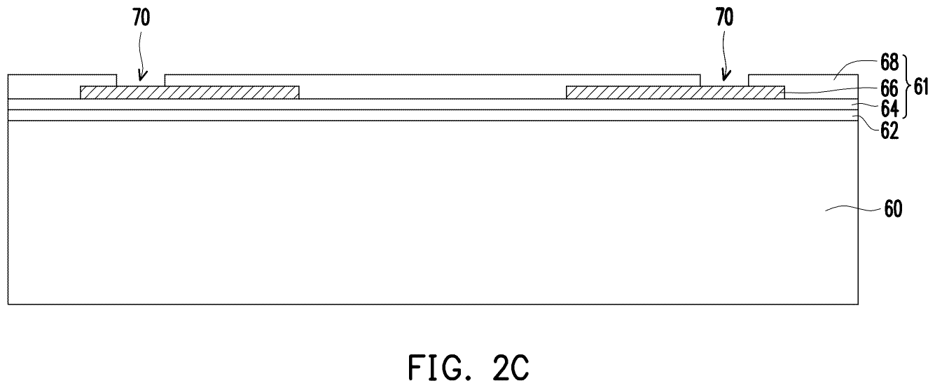

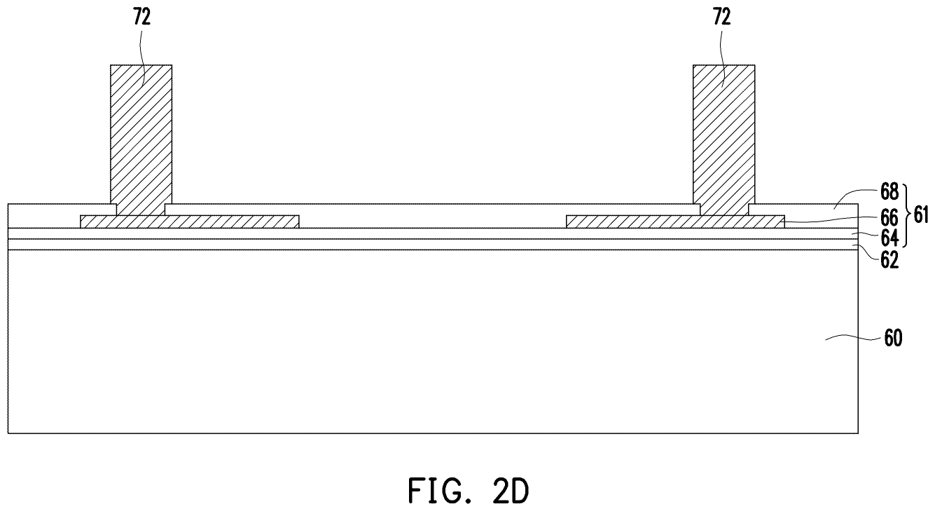

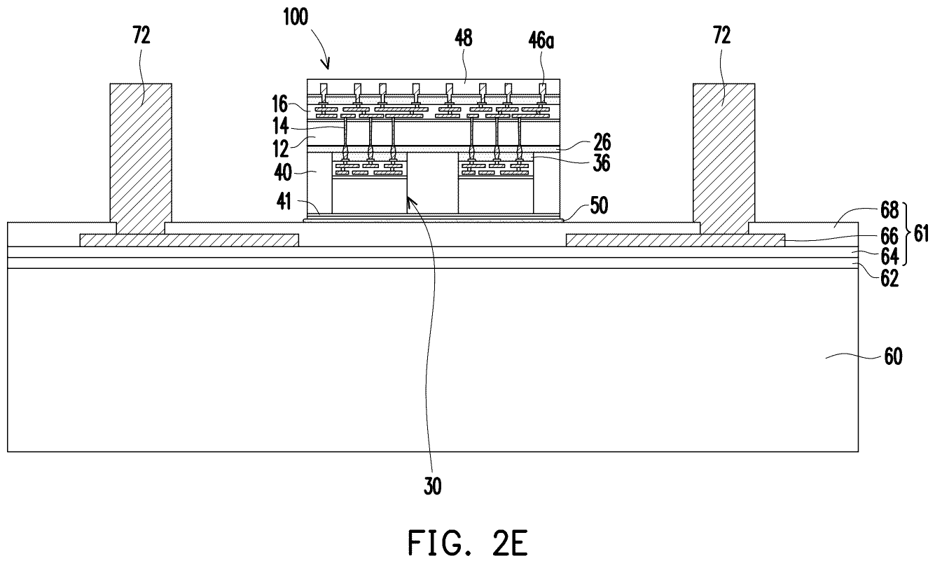

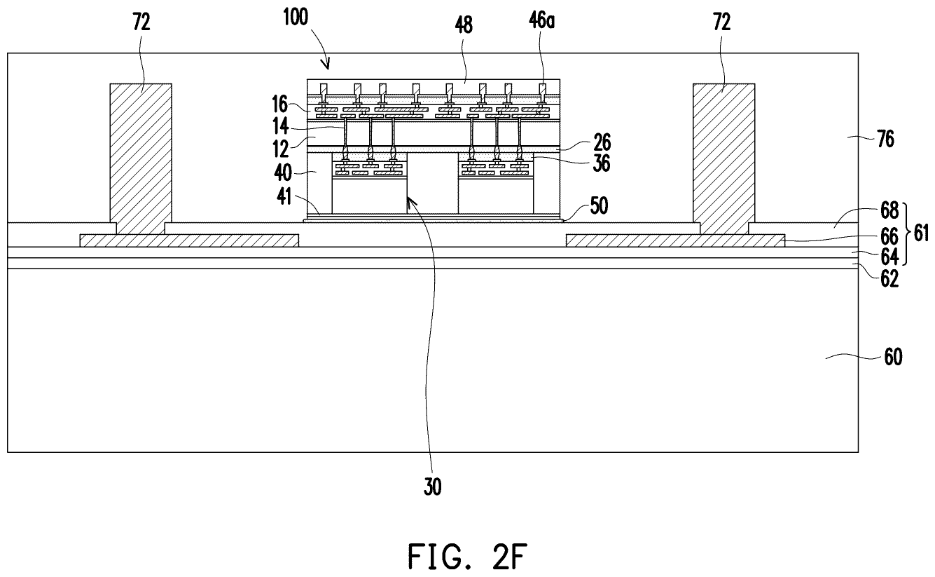

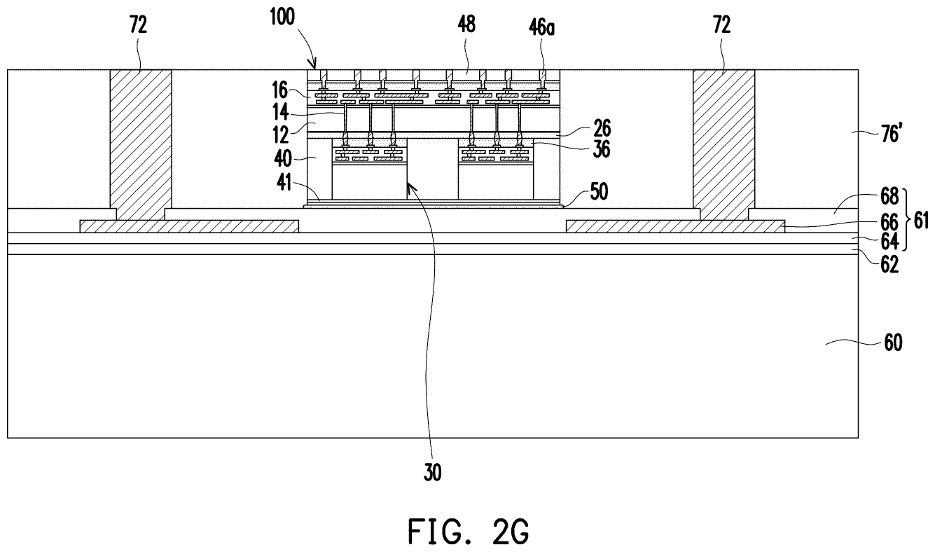

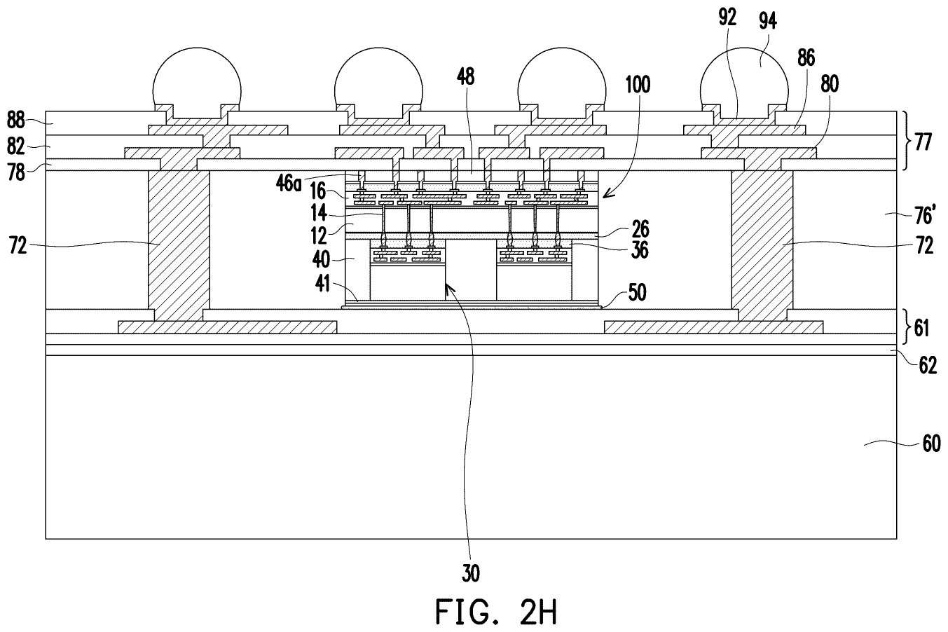

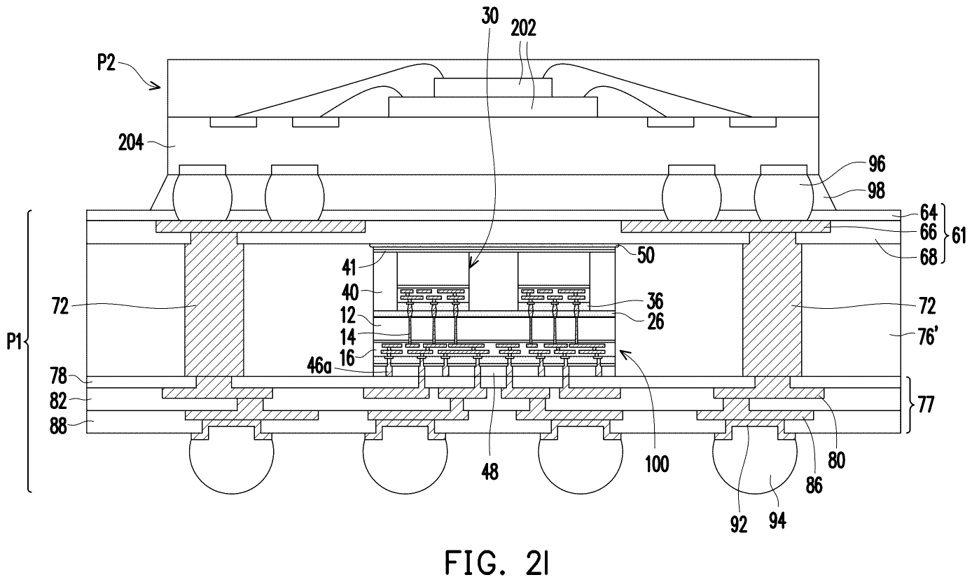

FIG. 2A through FIG. 2I are cross-sectional views schematically illustrating a process flow for fabricating a Package-on-Package (PoP) structure in accordance with some embodiments of the present disclosure.

Referring to FIG. 2A, a carrier 60 including a de-bonding layer 62 formed thereon is provided. In some embodiments, the carrier 60 is a glass substrate, a ceramic carrier, or the like. The carrier 60 may have a round top-view shape and a size of a silicon wafer. For example, carrier 60 may have an 8-inch diameter, a 12-inch diameter, or the like. The de-bonding layer 62 may be formed of a polymer-based material (e.g., a Light-To-Heat-Conversion (LTHC) material), which may be subsequently removed along with the carrier 60 from the overlying structures that will be formed in subsequent steps. In some embodiments, the de-bonding layer 62 is formed of an epoxy-based thermal-release material. In other embodiments, the de-bonding layer 62 is formed of an ultra-violet (UV) glue. The de-bonding layer 62 may be dispensed as a liquid and cured. In alternative embodiments, the de-bonding layer 62 is a laminate film and is laminated onto the carrier 60. The top surface of the de-bonding layer 62 is substantially planar.

Referring to FIGS. 2A through 2C, a redistribution structure 61 including a dielectric layer 64, redistribution wirings 66 and a dielectric layer 68 is formed on the de-bonding layer 62 such that the de-bonding layer 62 is between the carrier 60 and the dielectric layer 64 of the redistribution structure 61. As shown in FIG. 2A, the dielectric layer 64 is formed on the de-bonding layer 62. In some embodiments, the dielectric layer 64 is formed of a polymer, which may also be a photo-sensitive material such as PBO, polyimide, BCB, or the like, which may be easily patterned using a photolithography process followed by an etch process or other suitable patterning process. In some embodiments, the dielectric layer 64 is formed of a nitride such as silicon nitride, an oxide such as silicon oxide, PSG, BSG, BPSG, or the like. As shown in FIG. 2B, the redistribution wirings 66 are formed over the dielectric layer 64. The formation of the redistribution wirings 66 may include forming a seed layer (not shown) over the dielectric layer 64, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 66 as shown in FIG. 2B. In accordance with some embodiments, the seed layer includes a titanium layer and a copper layer over the titanium layer. The seed layer may be formed using, for example, Physical Vapor Deposition (PVD). The plating may be performed using, for example, electroless plating. As shown in FIG. 2C, the dielectric layer 68 is formed over the dielectric layer 64 to cover the redistribution wirings 66. The bottom surface of the dielectric layer 68 is in contact with the top surfaces of the redistribution wirings 66 and the dielectric layer 64. In accordance with some embodiments of the present disclosure, the dielectric layer 68 is formed of a polymer, which may be a photo-sensitive material such as PBO, polyimide, BCB, or the like. In some embodiments, the dielectric layer 68 is formed of a nitride such as silicon nitride, an oxide such as silicon oxide, PSG, BSG, BPSG, or the like. The dielectric layer 68 is then patterned to form openings 70 therein. Hence, portions of the redistribution wirings 66 are exposed through the openings 70 in the dielectric layer 68. FIG. 2C and the subsequent figures illustrate a single redistribution structure 61 having a single layer of redistribution wirings 66 for illustrative purposes and some embodiments may have a plurality of layers of redistribution wirings 66 by repeating the process discussed above.

Referring to FIG. 2D, after forming the redistribution structure 61 over the de-bonding layer 62 carried by the carrier 60, metal posts 72 are formed on the redistribution structure 61 and electrically connected to the redistribution wirings 66 of the redistribution structure 61. Throughout the description, the metal posts 72 are alternatively referred to as conductive through vias 72 since the metal posts 72 penetrate through the subsequently formed molding material (shown in FIG. 2G). In some embodiments, the conductive through vias 72 are formed by plating. The plating of the conductive through vias 72 may include forming a blanket seed layer (not shown) over the dielectric layer 68 and extending into the openings 70 shown in FIG. 2C, forming and patterning a photoresist (not shown), and plating the conductive through vias 72 on the portions of the seed layer that are exposed through the openings in the photoresist. The photoresist and the portions of the seed layer that were covered by the photoresist are then removed. The material of the conductive through vias 72 may include copper, aluminum, or the like. The conductive through vias 72 may have the shape of rods. The top-view shapes of the conductive through vias 72 may be circles, rectangles, squares, hexagons, or the like.

Referring FIG. 2E, after forming the conductive through vias 72, a chip stacking structure 100 illustrated in FIG. 1L is placed on the redistribution structure 61. The chip stacking structure 100 illustrated in FIG. 1L may be attached to the redistribution structure 61 by the attachment film 50. Only a single chip stacking structure 100 and its surrounding conductive through vias 72 are illustrated in FIG. 2E for illustrative purposes. The chip stacking structure 100 is surrounded by the conductive through vias 72. As illustrated in FIG. 2E, the lateral dimension of the attachment film 50 is slightly greater than the lateral dimension of the chip stacking structure 100. In other words, the footprint of the attachment film 50 is greater than that of the chip stacking structure 100. Furthermore, edges of the attachment film 50 may extend upwardly to cover the sidewalls of the chip stacking structure 100 after the chip stacking structure 100 is attached to the redistribution structure 61. As illustrated in FIG. 2E, the edges of the attachment film 50 may extend upwardly to cover the sidewalls of the multi-layered bonding film 41 as well as lower portions of the sidewalls of the insulating encapsulant 40.

Referring to FIG. 2F, an insulating encapsulation material 76 is formed over the redistribution structure 61 to cover the chip stacking structure 100 and the conductive through vias 72. The insulating encapsulation material 76 may be a molding compound (e.g., epoxy or other suitable resin) formed through an over-molding process. The insulating encapsulation material 76 not only fills the gaps between neighboring conductive through vias 72, but also fills the gaps between the conductive through vias 72 and the chip stacking structure 100. At this stage, the insulating encapsulation material 76 covers the top surface of the dielectric layer 48 of the chip stacking structure 100.

Next, as shown in FIG. 2G, a planarization such as a CMP process and/or a mechanical grinding process is performed to partially remove the insulating encapsulation material 76 and the dielectric layer 48 of the chip stacking structure 100 until the conductive through vias 72 and the conductive pillars 46a of the chip stacking structure 100 are revealed. After the insulating encapsulation material 76 is thinned, as illustrated in FIG. 2G, an insulating encapsulant 76′ is formed to laterally encapsulate the chip stacking structure 100 and the conductive through vias 72. Due to the planarization, the conductive through vias 72 penetrate though the insulating encapsulant 76′, the top ends of the conductive through vias 72 are substantially level or coplanar with the top surface of the dielectric layer 48, and are substantially level or coplanar with the top surface of the insulating encapsulant 76′, within process variations. In the illustrated exemplary embodiments, the planarization is performed until the conductive through vias 72 and the conductive pillars 46a of the chip stacking structure 100 are revealed.

Referring to FIG. 2H, a redistribution structure 77 including a dielectric layer 78, redistribution wirings 80, a dielectric layer 82, redistribution wirings 86, and a dielectric layer 88 is formed on the chip stacking structure 100 and the insulating encapsulant 76′. After forming the redistribution structure 77, solder regions including Under-Bump Metallurgies (UBMs) 92 and electrical connectors 94 disposed on the UBMs 92 are formed on the redistribution structure 77.

The dielectric layer 78 is formed to cover the dielectric 48, the conductive pillars 46a and the insulating encapsulant 76'. In some embodiments, the dielectric layer 78 is formed of a polymer such as PBO, polyimide, or the like. In some other embodiments, dielectric layer 78 is formed of silicon nitride, silicon oxide, or the like. Openings may be formed in the dielectric layer 78 to expose conductive through vias 72 and the conductive pillars 46a. The formation of the openings in the dielectric layer 78 may be performed through a photolithography process followed by an etch process or other suitable patterning process.

Next, the redistribution wirings 80 are formed to connect to the conductive pillars 46a and the conductive through vias 72. The redistribution wirings 80 may also interconnect the conductive pillars 46a and the conductive through vias 72. The redistribution wirings 80 may include metal traces (metal lines) over the dielectric layer 78 as well as metal vias extending into the openings defined in the dielectric layer 78 so as to electrically connect to the conductive through vias 72 and the conductive pillars 46a. In some embodiments, the redistribution wirings 80 are formed by a plating process, wherein each of the redistribution wirings 80 includes a seed layer (not shown) and a plated metallic material over the seed layer. The seed layer and the plated material may be formed of the same material or different materials. The redistribution wirings 80 may include a metal or a metal alloy including aluminum, copper, tungsten, and alloys thereof. The redistribution wirings 80 may be formed of non-solder materials. The via portions of the redistribution wirings 80 may be in physical contact with the top surfaces of the conductive through vias 72 and the conductive pillars 46a.

The dielectric layer 82 is then formed over the redistribution wirings 80 and the dielectric layer 78. The dielectric layer 82 may be formed using a polymer, which may be selected from the same candidate materials as those of the dielectric layer 78. For example, the dielectric layer 82 may include PBO, polyimide, BCB, or the like. In some embodiments, the dielectric layer 82 may include non-organic dielectric materials such as silicon oxide, silicon nitride, silicon carbide, silicon oxynitride, or the like. Openings may be also formed in the dielectric layer 82 to expose the redistribution wirings 80. The formation of the openings defined in the dielectric layer 82 may be performed through a photolithography process followed by an etch process or other suitable patterning process. The formation of the redistribution wirings 86 may adopt similar methods and materials to those for forming the redistribution wirings 80.

The dielectric layer 88, which may be a polymer layer, may be formed to cover the redistribution wirings 86 and the dielectric layer 82. The dielectric layer 88 may be selected from the same candidate polymers used for forming the dielectric layers 78 and 82. Openings may be formed in the dielectric layer 88 to expose the metal pad portions of redistribution wirings 86. The formation of the openings defined in the dielectric layer 88 may be performed through a photolithography process followed by an etch process or other suitable patterning process.

The formation of the UBMs 92 may include a deposition process followed by a patterning process. The formation of the electrical connectors 94 may include placing solder on the exposed portions of the UBMs 92 and then reflowing the solder to form solder balls. In some embodiments, the formation of the electrical connectors 94 includes performing a plating step to form solder regions over redistribution wirings 86 and then reflowing the solder regions. In some other embodiments, the electrical connectors 94 include metal pillars or metal pillars and solder caps, which may also be formed through plating. Throughout the description, the combined structure including the chip stacking structure 100, the conductive through vias 72, the insulating encapsulant 76′, the redistribution structure 61, the redistribution structure 77, the UBMs 92 and the electrical connectors 94 will be referred to as a wafer level package, which may be a composite wafer with a round top-view shape.

Referring to FIG. 2H and FIG. 2I, a de-bonding process is then performed such that the carrier 60 is de-bonded from the wafer level package. After performing the de-bonding process, the dielectric layer 64 of the redistribution structure 61 are revealed. During the de-bonding process, the de-bonding layer 62 is also removed from the wafer level package. The de-bonding may be performed by irradiating a light such as UV light or laser on the de-bonding layer 62 to decompose the de-bonding layer 62. In the de-bonding process, a tape (not shown) may be adhered onto the dielectric layer 88 and the electrical connectors 94. In subsequent steps, the carrier 60 and the de-bonding layer 62 are removed from the wafer level package. A singulation process is performed to singulate the wafer level package illustrated in FIG. 2H into multiple singulated integrated fanout packages P1 illustrated in FIG. 2I.

A patterning process is performed to form openings in the dielectric layer 64 to expose the redistribution wirings 66. The formation of the openings defined in the dielectric layer 64 may be performed through a photolithography process followed by an etch process or other suitable patterning process. Then, a top package P2 is provided and bonded with the integrated fanout package P1 (i.e., the bottom package) such that a PoP structure is formed. In some embodiments of the present disclosure, the bonding between the top package P2 and the integrated fanout package P1 is performed through electrical connectors (e.g., solder regions) 96, which joins the metal pad portions of the redistribution wirings 66 to the metal pads in the top package P2. An underfill 98 may be formed to fill the gap between the top package P2 and the integrated fanout package P1 such that the electrical connectors 96 are laterally encapsulated by the underfill 98, and reliability of the electrical connectors 96 can be enhanced. In some embodiments, the top package P2 includes semiconductor dies 202, which may be memory dies such as Static Random Access Memory (SRAM) dies, Dynamic Random Access Memory (DRAM) dies, or the like. The memory dies 202 may also be bonded to package substrate 204 in some exemplary embodiments.

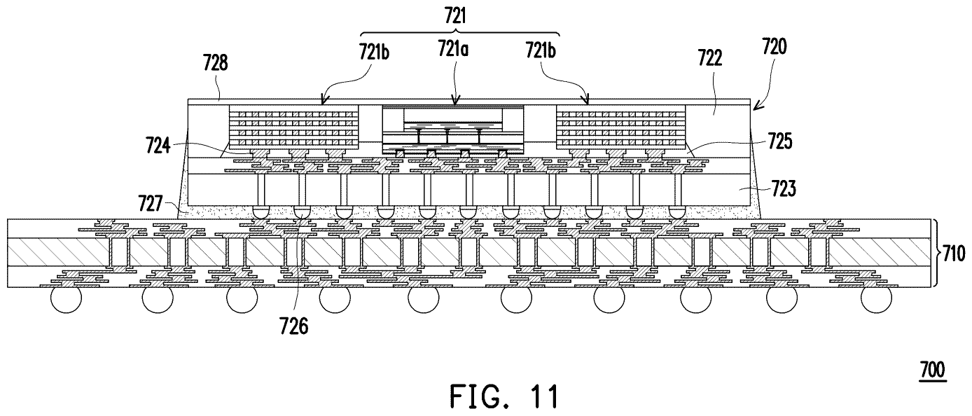

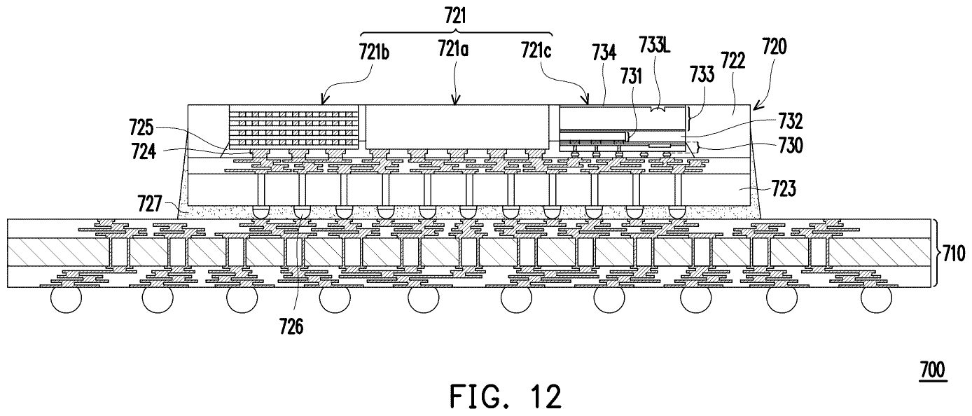

In the above-mentioned embodiments, the chip stacking structure 100 (e.g., SoIC structure) is applied in an Integrated Fan-out (InFO) package of a PoP structure for illustration purpose. However, the chip stacking structure 100 can be applied in other suitable types of packages, such as Chip-on-Wafer-on-Substrate (CoWoS) packages illustrated in FIGS. 11 and 12.

As illustrated in FIG. 2I, the PoP structure may include an InFO package P1 and a package P2 stacked over the InFO package P1. The InFO package includes a chip stacking structure 100 (e.g., an SoIC structure) with multi-layered bonding film 41 and an insulating encapsulant 76′. The chip stacking structure 100 may include a first semiconductor die 20, a second semiconductor die 30, an insulating encapsulant 40 and a multi-layered bonding film 41. The second semiconductor die 30 is disposed on and electrically connected to the first semiconductor die 20. The insulating encapsulant 40 is disposed on the first semiconductor die 20 and laterally encapsulating the second semiconductor die 30. The multi-layered bonding film 41 is disposed on a surface of the insulating encapsulant 40 and a surface of the second semiconductor die 30. The multi-layered bonding film 41 includes a planar surface. The surface of the insulating encapsulant 40 may substantially level with the surface of the second semiconductor die 30. In some embodiments, the multi-layered bonding film 41 includes a first dielectric layer 41a and a second dielectric layer 41b, wherein the first dielectric layer 41a is in contact with the surface of the insulating encapsulant 40 and the surface of the second semiconductor die 30, the second dielectric layer 41b covers the first dielectric layer 41a, and the second dielectric layer 41b has the planar surface. In some embodiments, the chip stacking structure 100 further includes an attachment film 50 covering the multi-layered bonding film 41, wherein the attachment film 50 is in contact with the planar surface of the second dielectric layer 41b of the multi-layered bonding film 41.

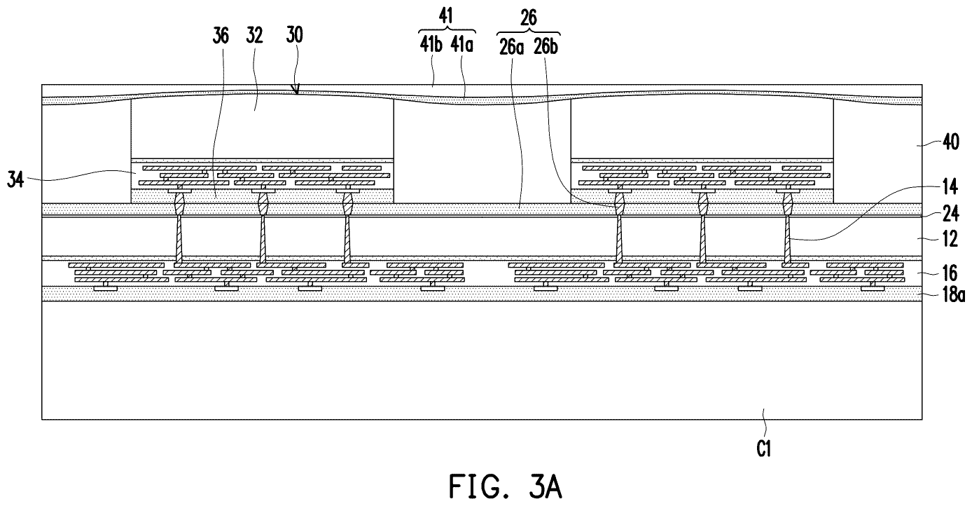

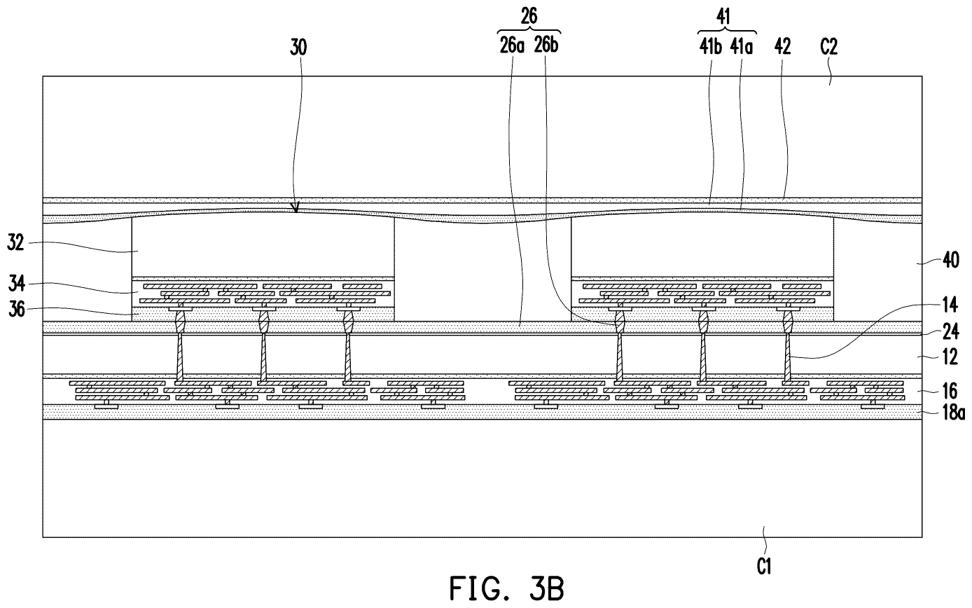

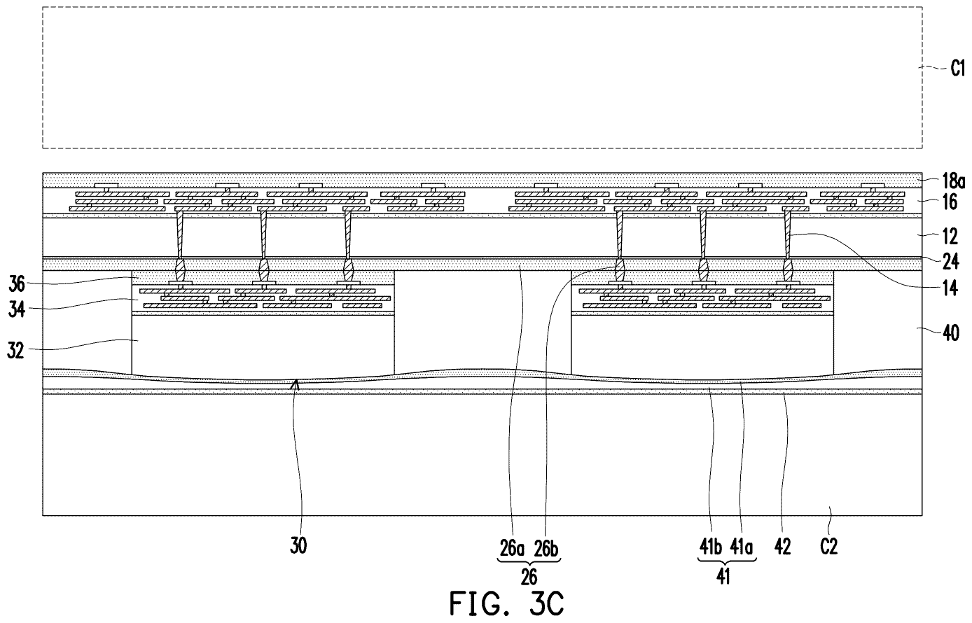

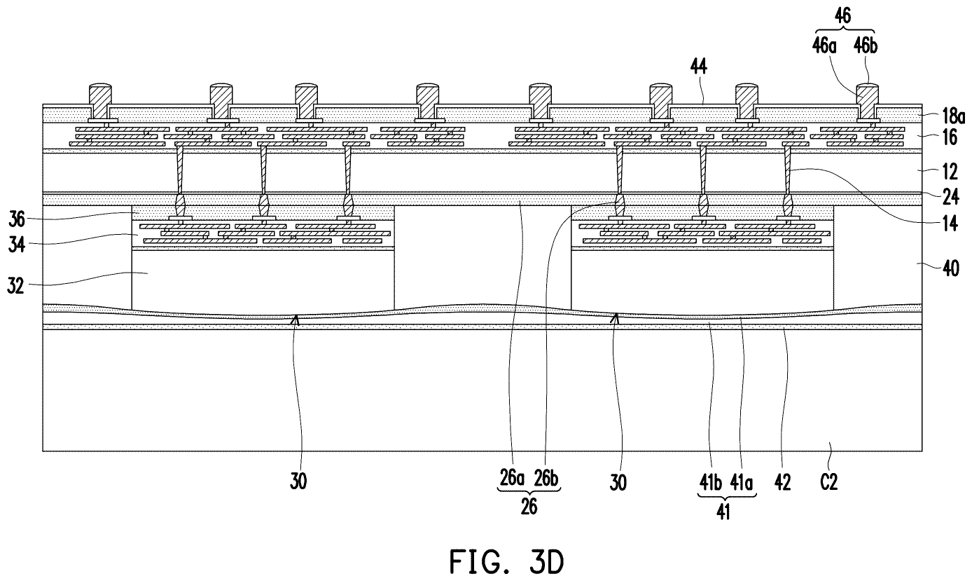

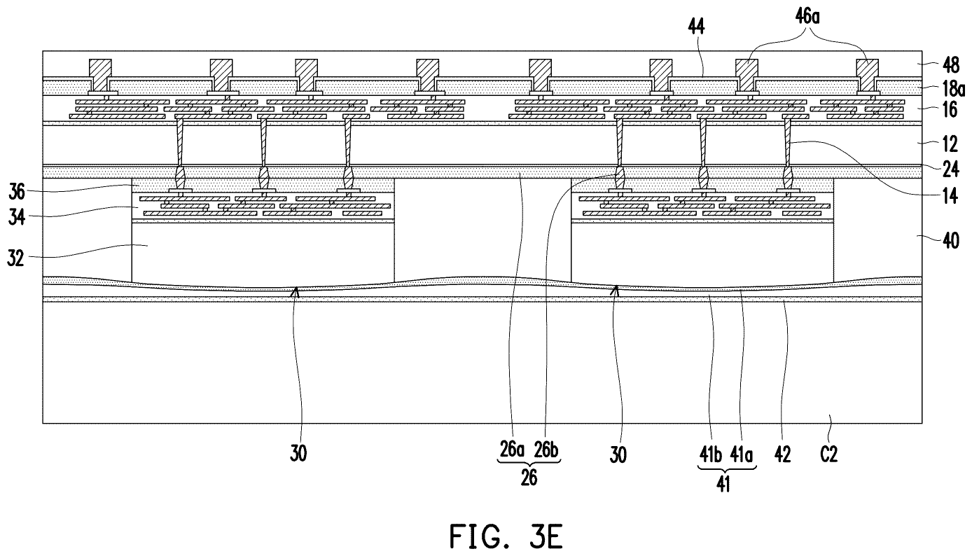

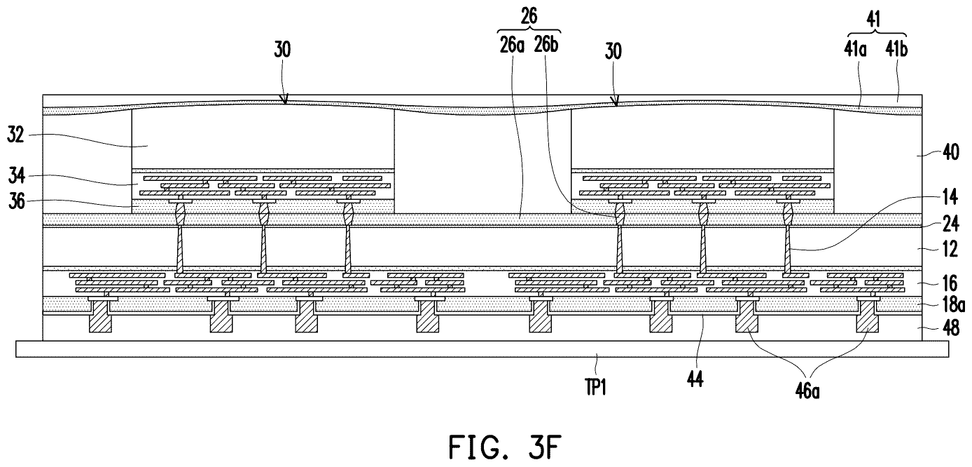

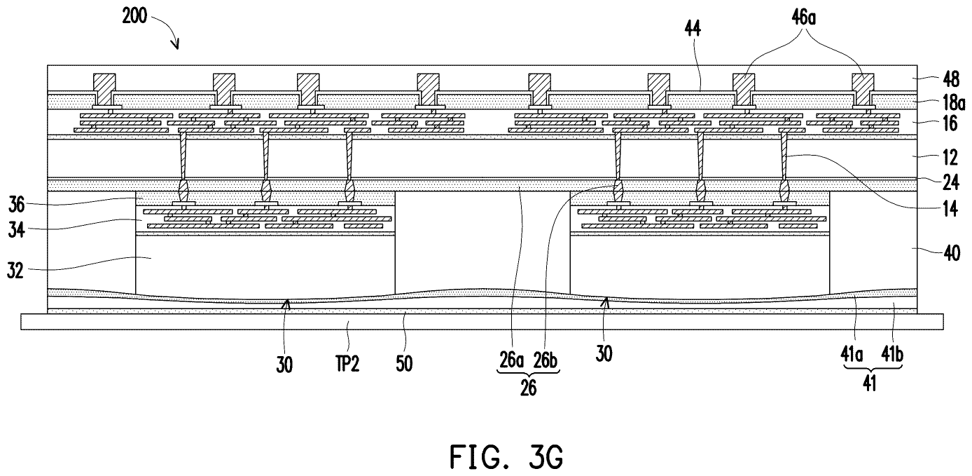

FIG. 3A through FIG. 3G are cross-sectional views schematically illustrating a process flow for fabricating chip stacking structures in accordance with some other embodiments of the present disclosure.

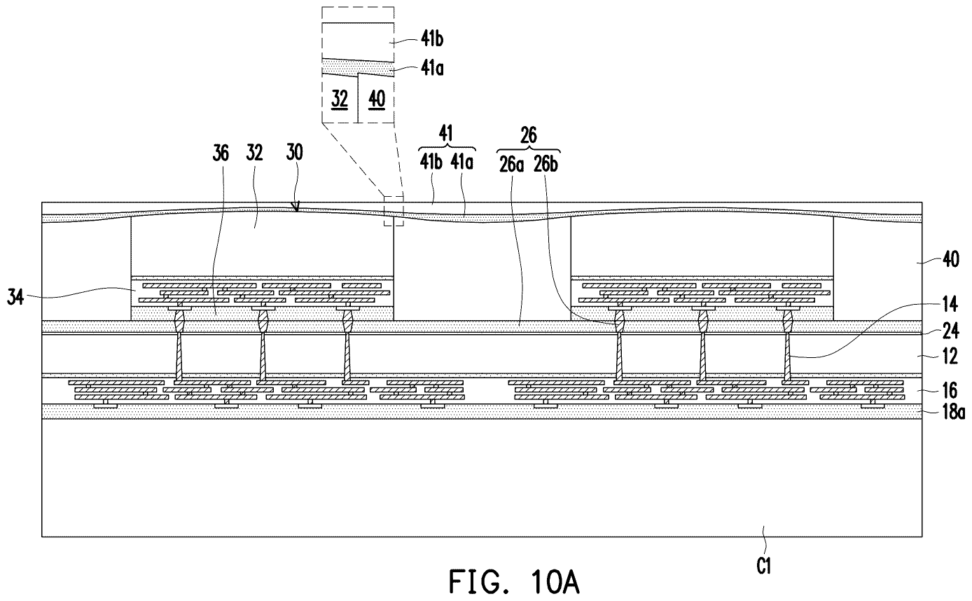

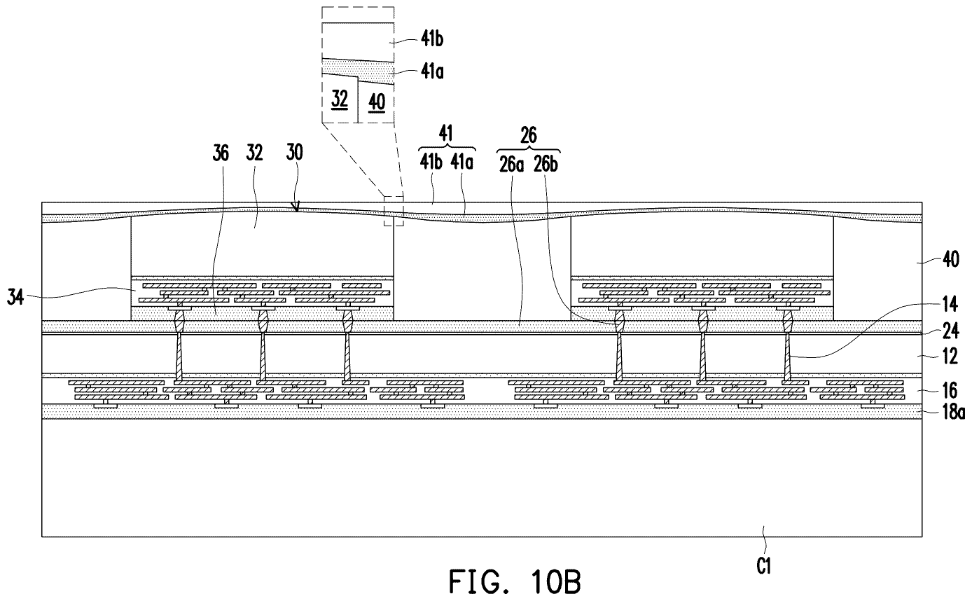

Referring to FIG. 3A and FIG. 1F, the process illustrated in FIG. 3A is similar that illustrated in FIG. 1F except that the surface of the insulating encapsulant 40 includes a concave surface, the surface (e.g., the back surface) of the second semiconductor die 30 includes a convex surface, and the bottommost dielectric layer (i.e., the first dielectric layer 41a among the multi-layered bonding film 41 is conformally formed on the concave surface of the insulating encapsulant 40 and the convex surface of the second semiconductor die 30. The first dielectric layer 41a is thicker than the second dielectric layer 41b. In the chip stacking structure 200, the second dielectric layer 41b among the multi-layered bonding film 41 has a planar surface, the first dielectric layer 41a includes first dielectric portions and second dielectric portions, the maximum thickness of the second dielectric portions of the first dielectric layer 41a is greater than the maximum thickness of the first dielectric portion of the first dielectric layer 41a, and the second dielectric layer 41b includes first dielectric portions and second dielectric portions, the maximum thickness of the first dielectric portion of the second dielectric layer 41b is greater than the maximum thickness of the second dielectric portions of the second dielectric layer 41b. The first dielectric portions are located above and cover the second semiconductor die 30, and the second dielectric portions are located above and cover the insulating encapsulant 40. As illustrated in FIG. 3A, the first dielectric layer 41a does not include a planar top surface, and the second dielectric layer 41b includes a planar top surface. Furthermore, the second dielectric layer 41b is in contact with and covered by the attachment film 50 (shown in FIG. 3G). The first dielectric layer 41a provides good thermal conductivity, and the second dielectric layer 41b is thick enough to well cover the topography provided by the second semiconductor die 30 and the insulating encapsulant 40 such that the second dielectric layer 41b of the multi-layered bonding film 41 may provide proper planarization function. For example, the thickness of the first dielectric layer 41 a ranges from about 500 angstroms to about 3000 angstroms, and the thickness of the second dielectric layer 41b ranges from about 200 angstroms to about 500 angstroms. Furthermore, the maximum thickness of the second semiconductor die 30 is greater than the thickness of the insulating encapsulant 40. For example, the difference between the maximum thickness of the second semiconductor die 30 and the thickness of the insulating encapsulant 40 ranges from about 0.1 micrometer to about 0.5 micrometer. It is noted that the insulating encapsulant 40 has sidewalls in contact with sidewalls of the second semiconductor dies 30, and the height of the sidewalls of the second semiconductor die 30 are substantially identical to the height of the sidewalls of the insulating encapsulant 40. In other words, there is no height difference between the sidewalls of the second semiconductor die 30 and the sidewalls of the insulating encapsulant 40. In some other embodiments, the sidewalls of the second semiconductor die 30 are higher than or lower than the sidewalls of the insulating encapsulant 40, as illustrated in FIGS. 10A and 10B. In other words, there is height difference (e.g., about 0.1 micrometer to about 0.5 micrometer) between the sidewalls of the second semiconductor die 30 and the sidewalls of the insulating encapsulant 40. In the embodiments illustrated in FIGS. 10A and 10B, step portions exit between the sidewalls of the second semiconductor die 30 and the sidewalls of the insulating encapsulant 40.

Referring to FIG. 3B through FIG. 3G and FIG. 1G and FIG. 1L, the process flow illustrated in FIG. 3B through FIG. 3G is similar to that illustrated in FIG. 1G and FIG. 1L. Accordingly, the details regarding to the process flow illustrated in FIG. 3B through FIG. 3G are omitted.

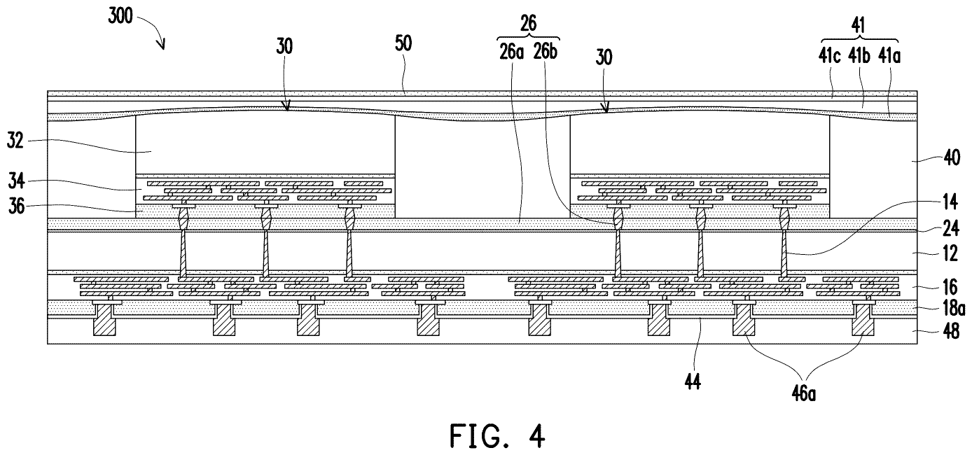

FIG. 4 through FIG. 7 are cross-sectional views schematically illustrating various chip stacking structures in accordance with some alternative embodiments of the present disclosure.

Referring to FIG. 4 and FIG. 3G, the chip stacking structure 300 illustrated in FIG. 4 is similar to the chip stacking structure 200 illustrated in FIG. 3G except that the multi-layered bonding film 41 of the chip stacking structure 300 further includes a third dielectric layer 41c covering the second dielectric layer 41b. In some embodiments, the second dielectric layer 41b and the third dielectric layer 41c are dielectric layers respectively having uniform thickness. Furthermore, the third dielectric layer 41c is in contact with and is covered by the attachment film 50.

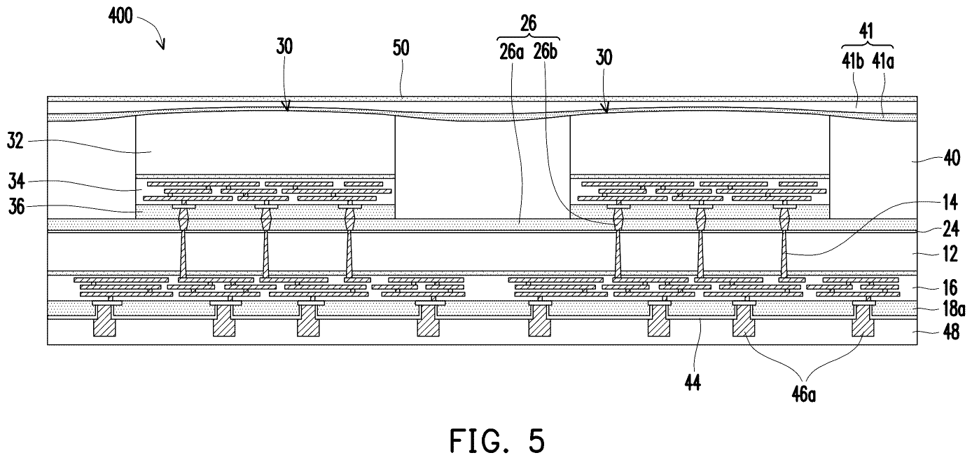

Referring to FIG. 5 and FIG. 1F, the chip stacking structure 400 illustrated in FIG. 5 is similar to that illustrated in FIG. 1F except that the surface of the insulating encapsulant 40 includes a convex surface, the surface (e.g., the back surface) of the second semiconductor die 30 includes a concave surface, and the topmost dielectric layer (i.e., the first dielectric layer 41a among the multi-layered bonding film 41 is conformally formed on the concave surface of the insulating encapsulant 40 and the convex surface of the second semiconductor die 30. The first dielectric layer 41a is thicker than the second dielectric layer 41b. In the chip stacking structure 200, the second dielectric layer 41b among the multi-layered bonding film 41 has a planar surface, the first dielectric layer 41a includes first dielectric portions and second dielectric portions, the maximum thickness of the first dielectric portion of the first dielectric layer 41a is greater than the maximum thickness of the second dielectric portions of the first dielectric layer 41a, and the second dielectric layer 41b includes first dielectric portions and second dielectric portions, the maximum thickness of the first dielectric portion of the second dielectric layer 41b is greater than the maximum thickness of the second dielectric portions of the second dielectric layer 41b. The first dielectric portions are located above and cover the second semiconductor die 30, and the second dielectric portions are located above and cover the insulating encapsulant 40. As illustrated in FIG. 5, the first dielectric layer 41a does not include a planar top surface, and the second dielectric layer 41b includes a planar top surface. The first dielectric layer 41a provides good thermal conductivity, and the second dielectric layer 41b is thick enough to well cover the topography provided by the second semiconductor die 30 and the insulating encapsulant 40 such that the second dielectric layer 41b of the multi-layered bonding film 41 may provide proper planarization function. For example, the thickness of the first dielectric layer 41a ranges from about 500 angstroms to about 3000 angstroms, and the thickness of the second dielectric layer 41b ranges from about 200 angstroms to about 500 angstroms. Furthermore, the maximum thickness of the insulating encapsulant 40 is greater than the thickness of the second semiconductor die 30. For example, the difference between the maximum thickness of the second semiconductor die 30 and the thickness of the insulating encapsulant 40 ranges from about 0.1 micrometer to about 0.5 micrometer. It is noted that the insulating encapsulant 40 has sidewalls in contact with sidewalls of the second semiconductor dies 30, and the height of the sidewalls of the second semiconductor die 30 are substantially identical to the height of the sidewalls of the insulating encapsulant 40. In other words, there is no height difference between the sidewalls of the second semiconductor die 30 and the sidewalls of the insulating encapsulant 40.

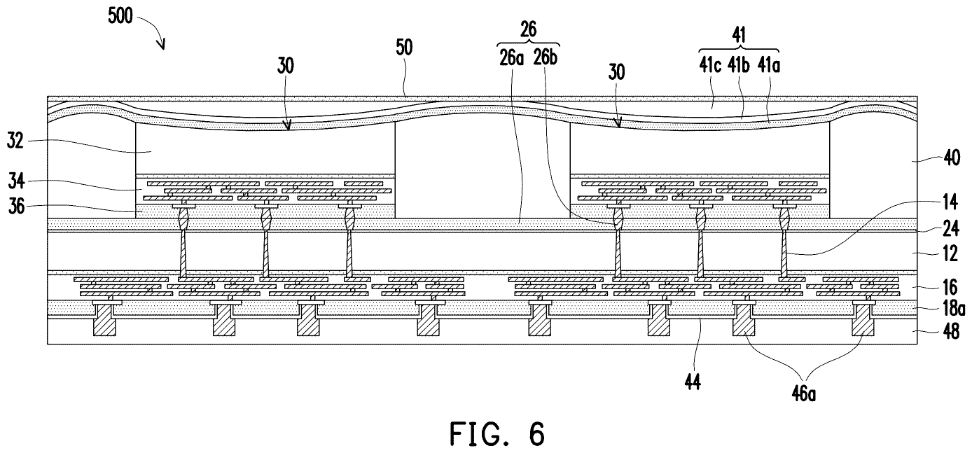

Referring to FIG. 6 and FIG. 4, the chip stacking structure 500 illustrated in FIG. 6 is similar to the chip stacking structure 300 illustrated in FIG. 4 except that both the first dielectric layer 41a and the second dielectric layer 41b conformally cover the concave and convex surface (or curved surface) which is provided by the second semiconductor die 30 and the insulating encapsulant 40. Furthermore, the third dielectric layer 41c of the multi-layered bonding film 41 includes first dielectric portions and second dielectric portions, the maximum thickness of the first dielectric portion of the third dielectric layer 41c is greater than the maximum thickness of the second dielectric portions of the third dielectric layer 41c, wherein the first dielectric portions cover the second semiconductor die 30, and the second dielectric portions cover the insulating encapsulant 40. As illustrated in FIG. 6, the third dielectric layer 41c includes dielectric patterns, the dielectric patterns cover first portions of the second dielectric layer 41b, second portions of the second dielectric layer 41b are uncovered by the third dielectric layer 41c, and wherein top surfaces of the second portions of the second dielectric layer 41b substantially levels with top surfaces of the dielectric patterns of the third dielectric layer 41c. Furthermore, both the second dielectric layer 41b and the third dielectric layer 41c are in contact with and covered by the attachment film 50.

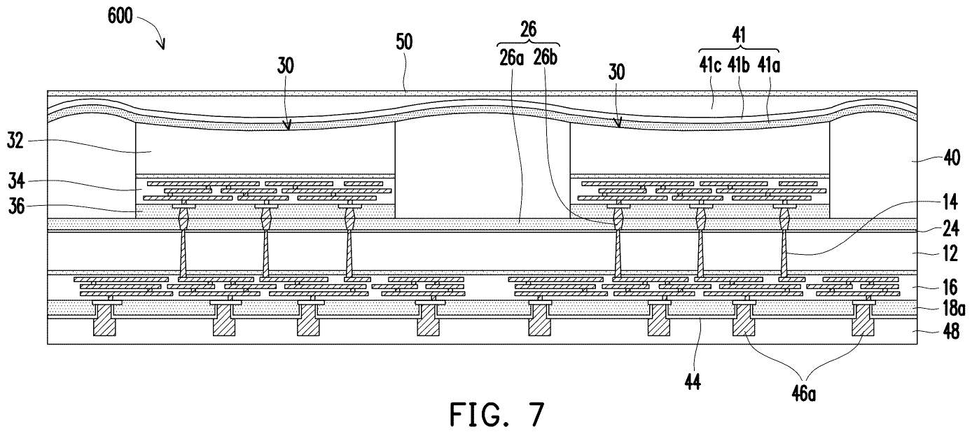

Referring to FIG. 6 and FIG. 7, the chip stacking structure 600 illustrated in FIG. 7 is similar to the chip stacking structure 500 illustrated in FIG. 6 except that the second dielectric layer 41b is entirely covered by the third dielectric layer 41c. The first dielectric layer 41a and the second dielectric layer 41b are not in contact with the attachment film 50. Furthermore, the first dielectric layer 41a and the second dielectric layer 41b are spaced apart from the attachment film 50 by the third dielectric layer 41c.

It is noted that the designs of the multi-layered bonding film 41 illustrated in FIG. 5 through FIG. 7 can be applied to the structure illustrated in FIG. 4. Furthermore, the number of dielectric layers in the multi-layered bonding film 41 is not limited to be two or three. The multi-layered bonding film 41 having more than three dielectric layers can also be applied to the structures illustrated in FIG. 3G and FIG. 4 through FIG. 7.

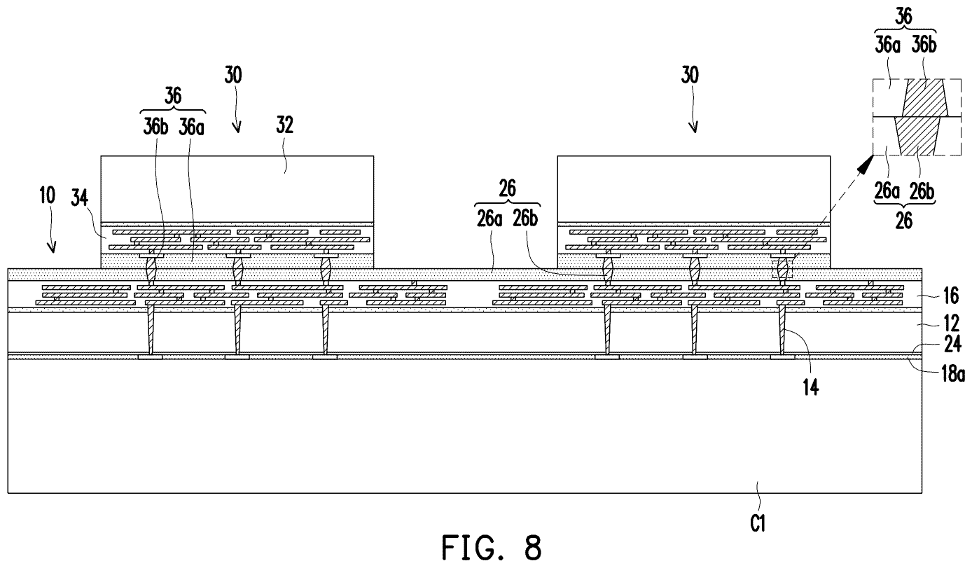

FIG. 8 is a cross-sectional view schematically illustrating the face-to-face bonding of the semiconductor wafer 10′ and the semiconductor dies 30 in accordance with some other embodiments of the present disclosure.

Referring to FIG. 1D and FIG. 8, the bonding between the semiconductor wafer 10′ and the semiconductor dies 30 is similar to the bonding between the semiconductor wafer 10 and the semiconductor dies 30 except that the bonding between the semiconductor wafer 10′ and the semiconductor dies 30 is a kind of face-to-face bonding. As illustrated in FIG. 8, the wafer 10′ may include a semiconductor substrate 12 (e.g., a semiconductor substrate), through substrate vias 14 embedded in the semiconductor substrate 12, an interconnect structure 16 disposed on the semiconductor substrate 12, and a bonding structure 26 disposed on the interconnect structure 16, wherein the through substrate vias 14 are electrically connected to the interconnect structure 16. The semiconductor substrate 12 of the wafer 10′ may include a crystalline silicon wafer. The semiconductor substrate 12 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the semiconductor substrate 12 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The semiconductor dies 30 are bonded to the semiconductor wafer 10′ through the bonding structure 26 and the bonding structures 36.

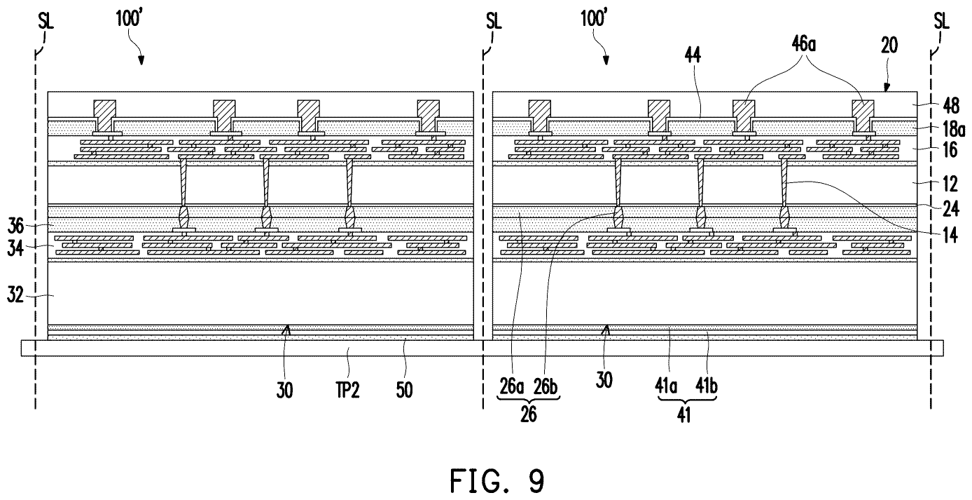

FIG. 9 is a cross-sectional view schematically illustrating chip stacking structure in accordance with some other embodiments of the present disclosure.

Referring to FIG. 1L and FIG. 9, the singulated chip stacking structures 100′ illustrated in FIG. 9 is similar to the singulated chip stacking structures 100 (i.e., SoIC structures) illustrated in FIG. 1L except that the singulated chip stacking structures 100′ does not include insulating encapsulant 40 since the insulating encapsulant 40 is removed during the singulation process shown in FIG. 1L. As illustrated in FIG. 9, in the singulated chip stacking structures 100′, the first semiconductor die 20 and the second semiconductor die 30 are substantially identical in lateral dimension. In other words, in the singulated chip stacking structures 100′, sidewalls of the first semiconductor die 20 substantially align with sidewalls of the second semiconductor die 30.

FIGS. 11 and 12 are cross-sectional views schematically illustrating various CoWoS packages in accordance with various alternative embodiments of the present disclosure.

Referring to FIG. 11, a CoWoS package structure 700 including a packaging substrate 710 and a semiconductor device 720 is provided. The semiconductor device 720 is mounted on the top surface of the packaging substrate 710. The semiconductor device 720 is electrically connected to the packaging substrate 710. The semiconductor device 720 may include at least one semiconductor die 721 and an insulating encapsulation 722 laterally encapsulating the at least one semiconductor die 721. The semiconductor device 720 may further includes an interposer wiring substrate 723, conductive terminals 724, a dielectric layer 725, conductive terminals 726, and a dielectric layer 727. As illustrated in FIG. 11, the packaging substrate 710 may be a printed circuit board or other suitable types of wiring substrate. The at least one semiconductor die 721 may be or include at least one first semiconductor die 721a and at least one second semiconductor die 721b. The at least one first semiconductor die 721a and the at least one second semiconductor die 721b are disposed on the interposer wiring substrate 723 in side-by-side manner.

In some embodiments, the first semiconductor die 721a includes a System-on-Chip (SoC) die, and the second semiconductor die 721b includes a High-Bandwidth-Memory (HBM) cube including stacked HBM memory dies and controller die for controlling the operation of the stacked HBM memory dies. In an embodiment illustrated in FIG. 11, the chip stacking structure 100 illustrated FIG. 1L is implemented as the first semiconductor die 721a illustrated in FIG. 11. It is noted that, in other embodiments, other types of SoIC structures, such as the chip stacking structures 200 through 600 can be implemented as the first semiconductor die 721a illustrated in FIG. 11. The first semiconductor die 721a and the second semiconductor die 721b are disposed on the interposer wiring substrate 723 and electrically connected to the interposer wiring substrate 73 through the conductive terminals 724. The conductive terminals 724 are disposed between the semiconductor dies 721 and the interposer wiring substrate 723. The conductive terminals 724 may be or include micro-bumps for electrically connecting the semiconductor dies 721 and the interposer wiring substrate 723. The dielectric layer 725 is disposed on the interposer wiring substrate 723. The dielectric layer 725 (e.g., an underfill) is disposed between the semiconductor dies 721 and the interposer wiring substrate 723 to laterally encapsulate the conductive terminals 724. In some embodiments, the dielectric layer 725 includes underfill material, molding compound, polymer, oxide materials, nitride materials or combinations thereof. Accordingly, shearing stress suffered by the conductive terminals 724 may be minimized by the dielectric layer 725, and the reliability of the conductive terminals 724 may be enhanced by the dielectric layer 725. The material of the dielectric layer 725 may be or include epoxy resin or other suitable dielectric materials.

As illustrated in FIG. 11, the insulating encapsulation 722 is disposed on the interposer wiring substrate 723 to laterally encapsulate the semiconductor dies 721 and the dielectric layer 725. The top surfaces (e.g., the back surfaces) of the semiconductor dies 721 are substantially level with the top surface of the insulating encapsulation 722, and the sidewalls of the insulating encapsulation 722 are substantially aligned with the sidewalls of the interposer wiring substrate 723. The conductive terminals 726 are disposed on the bottom surface of the interposer wiring substrate 723, and the interposer wiring substrate 723 is electrically connected to the packaging substrate 710 through the conductive terminals 726. The conductive terminals 726 may be or include Controlled Collapse Chip Connection bumps (C4 bumps) for electrically connecting the interposer wiring substrate 723 and the packaging substrate 710. The dielectric layer 727 (e.g., an underfill) is disposed on the packaging substrate 710. The dielectric layer 727 is disposed between the interposer wiring substrate 723 and the packaging substrate 710 so as to laterally encapsulate the conductive terminals 726. In some embodiments, the dielectric layer 727 includes underfill material, molding compound, polymer, oxide materials, nitride materials or combinations thereof. Furthermore, the dielectric layer 727 covers sidewalls of the interposer wiring substrate 723 as well as lower portions of sidewalls of insulating encapsulation 722.

The semiconductor dies 721 are electrically connected to the packaging substrate 710 through the interposer wiring substrate 723, the conductive terminals 724 and the conductive terminals 726. The interposer wiring substrate 723 may include a silicon interposer, an organic interposer or other suitable interposer wiring substrate. The interposer wiring substrate 723 may include conductive wirings formed thereon. Furthermore, the interposer wiring substrate 723 may include conductive through vias formed therein. The interposer wiring substrate 723 may be a silicon interposer wiring substrate with fine line pitch (e.g., sub-um pitch), an organic interposer wiring substrate with less aggressive fine line pitch (e.g., 4 um pitch) or an interposer wiring substrate with Local Silicon Interconnect (LSI) die. In an embodiment where the interposer wiring substrate 723 is a silicon interposer wiring substrate, the CoWoS package structure 700 is so-called a CoWoS-S package. In an embodiment where the interposer wiring substrate 723 is an organic interposer wiring substrate, the CoWoS package structure 700 is so-called a CoWoS-R package. In an embodiment where the interposer wiring substrate 723 is an interposer wiring substrate with Local Silicon Interconnect (LSI) die, the CoWoS package structure 700 is so-called a CoWoS-L package.

In some embodiments, the semiconductor device 720 may further include a backside metal layer 728 disposed on the top surfaces (e.g., the back surfaces) of the semiconductor dies 721 and the top surface of the insulating encapsulation 722. The backside metal layer 728 covers and is in contact with the top surfaces (e.g., the back surfaces) of the semiconductor dies 721 and the top surface of the insulating encapsulation 722. The backside metal layer 728 may be a single layered metallic structure or a multi-layered metallic structure. The backside metal layer 728 may be or include a copper layer or other metallic layer with favorable thermal conductivity.

Referring to FIG. 11 and FIG. 12, the CoWoS package structure 700′ illustrated in FIG. 12 is similar to the CoWoS package structure 700 illustrated in FIG. 11 except that the CoWoS package structure 700′ further includes a photonic device 721c disposed on the interposer wiring substrate 723. Furthermore, the CoWoS package structure 700′ does not include the backside metal layer 728 illustrated in FIG. 11. The first semiconductor die 721a, the second semiconductor die 721b and the photonic device 721c are disposed on the interposer wiring substrate 723 and electrically connected to the interposer wiring substrate 73 through the conductive terminals 724. The photonic device 721c may comprise a photonic die 730 and an electronic die 731 bonded through metal-to-metal bonding and dielectric-to-dielectric bonding. The photonic device 721c may further include a support substrate 732 and a protection film 733 having lens portion (e.g., Si/SiO₂ lens portion) 733L formed thereon, wherein the support substrate 732 is disposed on the photonic die 730, the support substrate 732 and the electronic die 731 are arranged in side-by-side manner, and the protection film 733 is disposed over and covers the support substrate 732 and the electronic die 731. In some embodiments, the bonded structure of the photonic die 730 and the electronic die 731 in the photonic device 721c may be one of the chip stacking structures 200 through 600. The photonic device 721c may be or include an edge-coupler or a grating coupler, depending on the position of the light input and output (for example, optical module with optical fiber). Furthermore, the first semiconductor die 721a, the second semiconductor die 721b and the photonic device die 721c are disposed on the interposer wiring substrate 723 in side-by-side manner.

In the above-mentioned embodiments, since the above-mentioned multi-layered bonding film designs in the chip stacking structure (e.g., SoIC structures) provide favorable planarization, reliability and bonding yields may be enhanced.

In accordance with some embodiments of the disclosure, a chip stacking structure including a first semiconductor die, a second semiconductor die, an insulating encapsulant and a multi-layered bonding film is provided. The second semiconductor die is disposed on and electrically connected to the first semiconductor die. The insulating encapsulant is disposed on the first semiconductor die and laterally encapsulating the second semiconductor die. The multi-layered bonding film is disposed on a surface of the insulating encapsulant and a surface of the second semiconductor die. The multi-layered bonding film includes a planar surface. In some embodiments, the surface of the insulating encapsulant substantially levels with the surface of the second semiconductor die. In some embodiments, the surface of the insulating encapsulant includes a concave surface, the surface of the second semiconductor die includes a convex surface, and a topmost dielectric layer among the multi-layered bonding film includes the planar surface. In some embodiments, a maximum thickness of the second semiconductor die is greater than a thickness of the insulating encapsulant. In some embodiments, the surface of the insulating encapsulant includes a convex surface, the surface of the second semiconductor die includes a concave surface, and a topmost dielectric layer among the multi-layered bonding film includes the planar surface. In some embodiments, a maximum thickness of the insulating encapsulant is greater than a thickness of the second semiconductor die. In some embodiments, the multi-layered bonding film includes a first dielectric layer and a second dielectric layer, wherein the first dielectric layer is in contact with the surface of the insulating encapsulant and the surface of the second semiconductor die, the second dielectric layer covers the first dielectric layer, and the second dielectric layer has the planar surface. In some embodiments, the multi-layered bonding film includes a first dielectric layer, a second dielectric layer and a third dielectric layer, wherein the first dielectric layer is in contact with the surface of the insulating encapsulant and the surface of the second semiconductor die, the second dielectric layer covers the first dielectric layer, the third dielectric layer covering the second dielectric layer, and the third dielectric layer has the planar surface. In some embodiments, the multi-layered bonding film includes a first dielectric layer, a second dielectric layer and a third dielectric layer, wherein the first dielectric layer is in contact with the surface of the insulating encapsulant and the surface of the second semiconductor die, the second dielectric layer covers the first dielectric layer, the third dielectric layer includes dielectric patterns, the dielectric patterns cover first portions of the second dielectric layer, second portions of the second dielectric layer are uncovered by the third dielectric layer, and wherein surfaces of the second portions of the second dielectric layer substantially levels with surfaces of the dielectric patterns. In some embodiments, the chip stacking structure further includes an attachment film covering the multi-layered bonding film.

In accordance with some other embodiments of the disclosure, a chip stacking structure including a first semiconductor die, a second semiconductor die, an insulating encapsulant and a multi-layered bonding film is provided. The second semiconductor die is disposed on and electrically connected to the first semiconductor die. The insulating encapsulant is disposed on the first semiconductor die and laterally encapsulating the second semiconductor die, wherein the second semiconductor die and the insulating encapsulant provide a concave and convex surface. The multi-layered bonding film is disposed on the concave and convex surface, wherein the multi-layered bonding film includes a first dielectric layer and a second dielectric layer, the first dielectric layer is in contact with the concave and convex surface, and the second dielectric layer is disposed on and in contact with the first dielectric layer. In some embodiments, the multi-layered bonding film further includes a third dielectric layer covering the second dielectric layer. In some embodiments, the multi-layered bonding film further includes a third dielectric layer, the third dielectric layer includes dielectric patterns covering first portions of the second dielectric layer, second portions of the second dielectric layer are uncovered by the third dielectric layer, and wherein surfaces of the second portions of the second dielectric layer substantially levels with surfaces of the dielectric patterns. In some embodiments, the insulating encapsulant includes a concave surface, and the second semiconductor die includes a convex surface. In some embodiments, a maximum thickness of the second semiconductor die is greater than a thickness of the insulating encapsulant. In some embodiments, the insulating encapsulant includes a convex surface, and the surface of the second semiconductor die includes a concave surface. In some embodiments, a maximum thickness of the insulating encapsulant is greater than a thickness of the second semiconductor die.

In accordance with some other embodiments of the disclosure, a method of fabricating a chip stacking structure is provided. A semiconductor wafer including first semiconductor dies is provided. Second semiconductor dies are bonded with the first semiconductor dies of the semiconductor wafer. A gap filling material is formed on the semiconductor wafer to laterally encapsulate the second semiconductor dies. The gap filling material is thinned until surfaces of the second semiconductor dies are revealed to form an insulating encapsulant laterally encapsulating the second semiconductor dies, wherein the second semiconductor dies and the insulating encapsulant provide a curved surface. A multi-layered bonding film is formed on the curved surface, wherein the multi-layered bonding film includes a planar surface. In some embodiments, after thinning the gap filling material until surfaces of the second semiconductor dies, the second semiconductor dies includes concave surfaces, and the insulating encapsulant includes convex surfaces. In some embodiments, after thinning the gap filling material until surfaces of the second semiconductor dies, the second semiconductor dies includes convex surfaces, and the insulating encapsulant includes concave surfaces.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor die comprising a first contact pad and a first bonding dielectric layer;
a second semiconductor die disposed over and electrically connected to the first semiconductor die, wherein the second semiconductor die comprises a second contact pad and a second bonding dielectric layer on a first side, the first contact pad is bonded to the second contact pad, the first bonding dielectric layer is bonded to the second bonding dielectric layer, and the first contact pad partially overlaps the second contact pad and partially overlaps the second bonding dielectric layer;
an insulating encapsulant disposed over the first semiconductor die and laterally encapsulating the second semiconductor die; and
an inter-layer film disposed over a second side of the second semiconductor die opposite to the first side, wherein the inter-layer film comprises a first dielectric layer over the second semiconductor die, and the first dielectric layer has a first thermal conductivity of larger than 10 W/m·K.

2. The chip stacking structure of claim 1, wherein a thermal conductivity of the first dielectric layer ranges from about 40 Wm⁻¹K⁻¹ to about 321 Wm⁻¹K⁻¹.

3. The chip stacking structure of claim 1, wherein the inter-layer film further comprises a second dielectric layer covering the first dielectric layer, and the first thermal conductivity is greater than a second thermal conductivity of the second dielectric layer.

4. The chip stacking structure of claim 3, wherein a material of the second dielectric layer comprises silicon nitride (SiNₓ, where x>0) layer or silicon oxide (SiOₓ, where x>0).

5. The chip stacking structure of claim 1, wherein the surface of the insulating encapsulant comprises a concave surface, the surface of the second semiconductor die comprises a convex surface, or the surface of the insulating encapsulant comprises a convex surface, the surface of the second semiconductor die comprises a concave surface.

6. The chip stacking structure of claim 1, wherein a maximum thickness of the insulating encapsulant is greater than a thickness of the second semiconductor die.

7. The chip stacking structure of claim 1, wherein the multi-layered bonding film further comprises:
a second dielectric layer covering the first dielectric layer.

8. The chip stacking structure of claim 1, wherein the multi-layered bonding film further comprises:
a second dielectric layer covering the first dielectric layer; and
a third dielectric layer covering the second dielectric layer.

9. The chip stacking structure of claim 1, wherein the multi-layered bonding film further comprises:
a second dielectric layer covering the first dielectric layer; and
a third dielectric layer comprising dielectric patterns, the dielectric patterns covering first portions of the second dielectric layer, second portions of the second dielectric layer being uncovered by the third dielectric layer, wherein surfaces of the second portions of the second dielectric layer substantially levels with surfaces of the dielectric patterns.

10. The chip stacking structure of claim 1, wherein a material of the first dielectric layer comprises aluminum nitride (AlN), BN, SiC, BeO, diamond, graphene, Cu, SiGe, TiO₂, poly-Si, Al₂O₃ or GaN.

11. A chip stacking structure, comprising:
a first semiconductor die comprising a first contact pad and a first bonding dielectric layer;
a second semiconductor die disposed on and electrically connected to the first semiconductor die, wherein the second semiconductor die comprises a second contact pad and a second bonding dielectric layer, the first contact pad is bonded to the second contact pad, the first bonding dielectric layer is bonded to the second bonding dielectric layer, the first contact pad partially overlaps the second contact pad and partially overlaps the second bonding dielectric layer; and
an inter-layered film formed over the second semiconductor die, wherein the inter-layered film has a first region with a first thickness and a second region with a second thickness, and the first thickness is different from the first thickness,
wherein a surface topography of the inter-layered film is defined as a height difference between a highest point and a lowest point within a 1-millimeter height, wherein the first surface has a first surface topography of larger than 30 angstroms, the second surface has a second surface topography of less than 30 angstroms,
wherein the inter-layered film comprises a first dielectric layer and a second dielectric layer covering the first dielectric layer.

12. The chip stacking structure of claim 11, wherein the inter-layered film further comprises:
a third dielectric layer covering the second dielectric layer.

13. The chip stacking structure of claim 11, wherein the inter-layered film further comprises:
a third dielectric layer comprising dielectric patterns, the dielectric patterns covering first portions of the second dielectric layer, second portions of the second dielectric layer being uncovered by the third dielectric layer, wherein surfaces of the second portions of the second dielectric layer substantially levels with surfaces of the dielectric patterns.

14. The chip stacking structure of claim 1 further comprising an insulating encapsulant disposed on the first semiconductor die and laterally encapsulating the second semiconductor die, wherein the insulating encapsulant comprises a concave surface, and the second semiconductor die comprises a convex surface.

15. The chip stacking structure of claim 14, wherein a maximum thickness of the second semiconductor die is greater than a thickness of the insulating encapsulant.

16. The chip stacking structure of claim 11 further comprising an insulating encapsulant disposed on the first semiconductor die and laterally encapsulating the second semiconductor die, wherein the insulating encapsulant comprises a convex surface, and the surface of the second semiconductor die comprises a concave surface.

17. The chip stacking structure of claim 16, wherein a maximum thickness of the insulating encapsulant is greater than a thickness of the second semiconductor die.

18. A method of fabricating a chip stacking structure, comprising:
providing a semiconductor wafer comprising first semiconductor dies;
bonding second semiconductor dies with the first semiconductor dies of the semiconductor wafer;
forming a gap filling material on the semiconductor wafer to encapsulate the second semiconductor dies;
thinning the gap filling material to form an insulating encapsulant laterally encapsulating the second semiconductor dies, wherein the second semiconductor dies and the insulating encapsulant provide a curved surface; and
forming a multi-layered bonding film on the curved surface, wherein the multi-layered bonding film comprises a planar surface.

19. The method of claim 18, wherein after thinning the gap filling material until surfaces of the second semiconductor dies, the second semiconductor dies comprises concave surfaces, and the insulating encapsulant comprises convex surfaces.

20. The method of claim 18, wherein after thinning the gap filling material until surfaces of the second semiconductor dies, the second semiconductor dies comprises convex surfaces, and the insulating encapsulant comprises concave surfaces.
